(19) United States
(12) Patent Application Publication
(10) Pub. No.: US 2025/0234103 A1
(43) Pub. Date: Jul. 17, 2025

(54) IMAGE SENSOR AND ELECTRONIC APPARATUS INCLUDING THE IMAGE SENSOR

(71) Applicant: SAMSUNG ELECTRONICS CO., LTD., Suwon-si (KR)

(72) Inventors: Sungmo AHN, Suwon-si (KR); Sookyung ROH, Suwon-si (KR); Hyochul KIM, Suwon-si (KR); Younggeun ROH, Suwon-si (KR); Sangeun MUN, Suwon-si (KR); Kyungbae PARK, Suwon-si (KR); Sungyoung YUN, Suwon-si (KR); Hyongeuk LEE, Suwon-si (KR)

(73) Assignee: SAMSUNG ELECTRONICS CO., LTD., Suwon-si (KR)

(21) Appl. No.: 19/016,542

(22) Filed: Jan. 10, 2025

(30) Foreign Application Priority Data
Jan. 11, 2024 (KR) 10-2024-0004862

(51) Int. Cl. H04N 25/13; H04N 25/77

(52) U.S. Cl. CPC H04N 25/134; H04N 25/77

(57) ABSTRACT

An image sensor including: a sensor substrate including a plurality of pixels, wherein the plurality of pixels includes a first pixel and a fourth pixel configured to detect green light, a second pixel configured to detect blue light, and a third pixel configured to detect red light, and wherein each pixel of the plurality of pixels includes an inorganic photoelectric conversion material; a color separation lens array apart from the sensor substrate in a first direction, wherein the color separation lens array is configured to separate incident light according to wavelengths, and to condense the separated incident light onto the plurality of pixels; an organic photoelectric conversion layer between the sensor substrate and the color separation lens array; and a spectroscopic filter layer between the organic photoelectric conversion layer and the color separation lens array.

### CROSS-REFERENCE TO RELATED APPLICATION

This application is based on and claims priority under 35 U.S.C. § 119 to Korean Patent Application No. 10-2024-0004862, filed on Jan. 11, 2024, in the Korean Intellectual Property Office, the disclosure of which is incorporated by reference herein in its entirety.

### BACKGROUND

### 1. Field

The disclosure relates to an image sensor and an electronic apparatus including the same.

### 2. Description of Related Art

An image sensor may use a color filter to detect the color of incident light. However, because the color filter absorbs light other than light of its own color, light usage efficiency may be reduced. For example, when a red, green, and blue (RGB) color filter is used, only ⅓ of incident light may be transmitted and the remaining ⅔ of incident light may be absorbed and thus, light use efficiency may only be about 33%. Accordingly, most of the light loss of the image sensor may occur in the color filter. As a result, it may be beneficial to separate the color provided to each pixel of the image sensor without using color filters.

### SUMMARY

Provided is an image sensor including a color separation lens array that may separate and condense incident light according to wavelengths.

Also provided is an image sensor with improved color accuracy and sensing sensitivity.

Additional aspects will be set forth in part in the description which follows and, in part, will be apparent from the description, or may be learned by practice of the presented embodiments of the disclosure.

In accordance with an aspect of the disclosure, an image sensor includes: a sensor substrate including a plurality of pixels, wherein the plurality of pixels includes a first pixel and a fourth pixel configured to detect green light, a second pixel configured to detect blue light, and a third pixel configured to detect red light, and wherein each pixel of the plurality of pixels includes an inorganic photoelectric conversion material; a color separation lens array apart from the sensor substrate in a first direction, wherein the color separation lens array is configured to separate incident light according to wavelengths, and to condense the separated incident light onto the plurality of pixels; an organic photoelectric conversion layer between the sensor substrate and the color separation lens array; and a spectroscopic filter layer between the organic photoelectric conversion layer and the color separation lens array.

The organic photoelectric conversion layer may include a material configured to absorb a photon to generate an exciton.

The organic photoelectric conversion layer may include at least one from among polyacene, rylene, rubrene, and biradicaloid.

The organic photoelectric conversion layer may have a thickness of 100 nanometers (nm) or less.

The image sensor may further include an interlayer between the sensor substrate and the organic photoelectric conversion layer.

The plurality of pixels may be included in a unit pixel group from among a plurality of unit pixel groups included in the sensor substrate, and the organic photoelectric conversion layer may include a single layer facing the plurality of unit pixel groups.

The organic photoelectric conversion layer may include a plurality of cells facing the plurality of pixels.

Each cell of the plurality of cells may include an organic photoelectric material having a thickness corresponding to a color of a pixel facing the each cell.

Each cell of the plurality of cells may include an organic photoelectric material having a material corresponding to a color of a pixel facing the each cell.

The plurality of cells may include a first cell facing the first pixel, a second cell facing the second pixel, a third cell facing the third pixel, and a fourth cell facing the fourth pixel,
each of the first cell, the third cell, and the fourth cell may include an organic photoelectric material, and the second cell may be a dummy cell that does not include the organic photoelectric material.

The plurality of pixels may include a plurality of first pixels corresponding to different chief ray angles, the plurality of first pixels may include a first first pixel corresponding to a first chief ray angle, and a second first pixel corresponding to a second chief ray angle, the first chief ray angle may be greater than the second chief ray angle, and a thickness of an organic photoelectric material included in a first cell facing the first first pixel may be less than a thickness of the organic photoelectric material included in a second cell facing the second first pixel.

The spectroscopic filter layer may include a plurality of spectroscopic filters facing the plurality of pixels, and each spectroscopic filter of the plurality of spectroscopic filters may have a transmission spectrum corresponding to a color of a pixel facing the each spectroscopic filter.

A first spectroscopic filter from among the plurality of spectroscopic filters may include two first spectroscopic filters having different chief ray angle positions and different structures from each other.

Each pixel of the plurality of pixels may include a plurality of light detection cells, and a size of the each spectroscopic filter may be equal to a size of a light detection cell facing the each spectroscopic filter from among the plurality of light detection cells.

The plurality of spectroscopic filters may include a Fabry-Perot resonator.

The each spectroscopic filter may include a resonator having a thickness corresponding to the color of the pixel facing the each spectroscopic filter.

The each spectroscopic filter may include a plurality of nanostructures.

A size of the plurality of nanostructures included in the each spectroscopic filter may correspond to the color of the pixel facing the each spectroscopic filter.

The sensor substrate may include: a first pixel group including a plurality of first pixels arranged adjacently and continuously; a second pixel group including a plurality of second pixels arranged adjacently and continuously; a third pixel group including a plurality of third pixels arranged adjacently and continuously; and a fourth pixel group including a plurality of fourth pixels arranged adjacently and continuously, wherein the spectroscopic filter layer may include: a first spectroscopic filter facing one of the plurality of first pixels included in the first pixel group; a second spectroscopic filter facing one of the plurality of second pixels included in the second pixel group; a third spectroscopic filter facing one of the plurality of third pixels included in the third pixel group; and a fourth spectroscopic filter facing one of the plurality of fourth pixels included in the fourth pixel group.

In accordance with an aspect of the disclosure, an electronic apparatus includes: a lens assembly including at least one lens and configured to form an optical image of an object; an image sensor configured to convert the optical image into an electronic signal; and a processor configured to process the electronic signal, wherein the image sensor includes: a sensor substrate including a plurality of pixels, wherein the plurality of pixels includes a first pixel and a fourth pixel configured to detect green light, a second pixel configured to detect blue light, and a third pixel configured to detect red light, wherein the plurality of pixels includes an inorganic photoelectric conversion material; a color separation lens array apart from the sensor substrate in a first direction, wherein the color separation lens array is configured to separate incident light according to wavelengths and to condense the separated incident light onto the plurality of pixels; an organic photoelectric conversion layer between the sensor substrate and the color separation lens array; and a spectroscopic filter layer between the organic photoelectric conversion layer and the color separation lens array.

In accordance with an aspect of the disclosure, an image sensor includes: a sensor substrate including a plurality of pixels, wherein each pixel of the plurality of pixels includes an inorganic photoelectric conversion material; an organic photoelectric conversion layer on the sensor substrate; and a spectroscopic filter layer on the organic photoelectric conversion layer; and a color separation lens array spaced apart from the sensor substrate by the organic photoelectric conversion layer and the spectroscopic filter array, wherein the color separation lens array is configured to separate incident light into light having a plurality of wavelengths corresponding to the plurality of pixels, and to condense the light having a particular wavelength through the organic photoelectric conversion layer and the spectroscopic filter layer onto a corresponding pixel from among the plurality of pixels.

A thickness of the organic photoelectric conversion layer may be greater in a center portion of the organic photoelectric conversion layer than in a peripheral portion of the organic photoelectric conversion layer.

When the organic photoelectric conversion layer has a greater chief ray angle (CRA) at a first position of the organic photoelectric conversion layer than a second position of the organic photoelectric conversion layer, a thickness of the organic photoelectric conversion layer at the first position may be less than a thickness of the organic photoelectric conversion layer at the second position.

### BRIEF DESCRIPTION OF THE DRAWINGS

The above and other aspects, features, and advantages of certain embodiments of the present disclosure will be more apparent from the following description taken in conjunction with the accompanying drawings, in which:

FIG. 1 is a block diagram of an image sensor according to an embodiment;

FIG. 2A is a plan view showing a color arrangement shown by a pixel array of an image sensor according to an embodiment.

FIGS. 2B and 2C are plan views showing a sensor substrate and a color separation lens array provided in the pixel array according to an embodiment;

FIGS. 3A and 3B are cross-sectional views of a pixel array, according to an embodiment, shown in different cross-sections;

FIG. 4 is a plan view of an exemplary arrangement of nanoposts provided in a color separation lens array of a pixel array, according to an embodiment;

FIG. 5 is a plan view of an arrangement of first to fourth spectroscopic filters of a spectroscopic filter layer provided in a pixel array with respect to a sensor substrate;

FIG. 6 is a graph showing a color separation performance of a pixel array according to a comparative example;

FIG. 7 is a graph showing a color separation performance of a pixel array according to an embodiment;

FIG. 8 is a cross-sectional view of an example of a structure of a spectroscopic filter that may be provided in a pixel array, according to an embodiment;

FIG. 9 is a cross-sectional view of another example of a structure of a spectroscopic filter that may be provided in a pixel array, according to an embodiment;

FIGS. 10A and 10B are cross-sectional views showing a pixel array according to an embodiment;

FIGS. 11A and 11B are cross-sectional views showing a pixel array according to an embodiment;

FIG. 12 is a cross-sectional view showing a pixel array according to an embodiment;

FIG. 13 is a cross-sectional view showing the pixel array and the chief ray angle, according to an embodiment;

FIG. 14A is a plan view showing a color arrangement of a pixel array according to an embodiment, FIG. 14B is a plan view showing a pixel arrangement of a sensor substrate provided in the pixel array of FIG. 14A, and FIG. 14C is a plan view showing an arrangement of the pixel corresponding areas corresponding to the unit pixel group of FIG. 14B;

FIGS. 15A and 15B are cross-sectional views showing the pixel array of FIG. 14A in different cross-sections;

FIG. 16 is a block diagram schematically showing an electronic apparatus including an image sensor according to embodiments; and

FIG. 17 is a block diagram schematically showing a camera module provided in an electronic apparatus.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

Hereinafter, embodiments will be described in detail with reference to the accompanying drawings. The embodiments of the disclosure are capable of various modifications and may be embodied in many different forms. In the drawings, like reference numerals denote like elements, and sizes of each component may be exaggerated for clarity and convenience in explanation.

It will be understood that when an element or layer is referred to as being “on” or “above” another element or layer, the element or layer may be directly on another element or layer or intervening elements or layers.

It will be understood that, although the terms “first”, “second”, etc. may be used herein to describe various elements, these terms are only used to distinguish one element from another. These terms do not limit the difference between materials or structures of the components.

An expression used in the singular encompasses the expression of the plural, unless it has a clearly different meaning in the context. It will be further understood that when a portion is referred to as “including” another component, the portion may not exclude another component but may further include another component unless the context states otherwise.

Also, the terms “ . . . unit”, “ . . . module” used herein specify a unit for processing at least one function or operation, and this may be implemented with hardware or software or a combination of hardware and software.

The use of the terms of “the above-described” and similar indicative terms may correspond to both the singular forms and the plural forms.

With respect to operations included in a method, the operations may be performed in any appropriate sequence unless the description of the sequence of operations or the context clearly indicates otherwise. In addition, the use of any and all examples, or exemplary language (e.g., “such as”) provided herein, is intended merely to better illuminate the disclosure and does not pose a limitation on the scope of the disclosure unless clearly indicated otherwise.

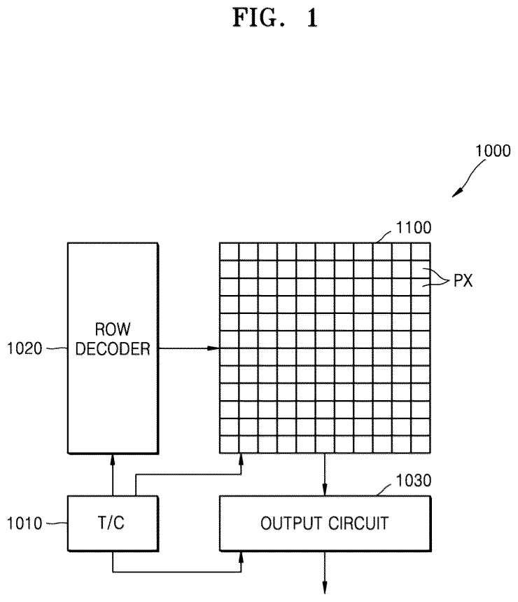

Referring to FIG. 1, an image sensor 1000 may include a pixel array 1100, a timing controller 1010 (illustrated as “T/C”), a row decoder 1020, and an output circuit 1030. The image sensor 1000 may be a charge coupled device (CCD) image sensor or a complementary metal oxide semiconductor (CMOS) image sensor.

The pixel array 1100 may include pixels PX arranged two-dimensionally along rows and columns. The row decoder 1020 may select one of the rows of the pixel array 1100 in response to the row address signal output from the timing controller 1010. The output circuit 1030 may output an optical sensing signal by column unit from a plurality of pixels PX arranged along the selected row. To this end, the output circuit 1030 may include a column decoder and an analog to digital converter (ADC). For example, the output circuit 1030 may include a plurality of ADCs respectively arranged in the columns between the column decoder and the pixel array 1100 or a single ADC arranged on an output terminal of the column decoder. The timing controller 1010, the row decoder 1020, and the output circuit 1030 may be implemented as one chip or respective chips. A processor for processing an image signal output by the output circuit 1030 may be implemented as one chip together with the timing controller 1010, the row decoder 1020, and the output circuit 1030.

The pixel array 1100 may include a plurality of pixels PX that detect light of different wavelengths. The arrangement of the pixels PX may be implemented in various ways. The pixel array 1100 may be provided with a color separation lens array that separates incident light by wavelengths and causes light of different wavelengths to be incident on the plurality of pixels PX.

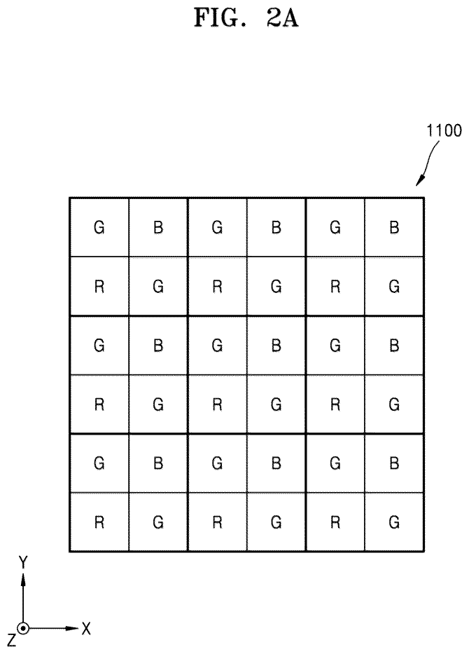

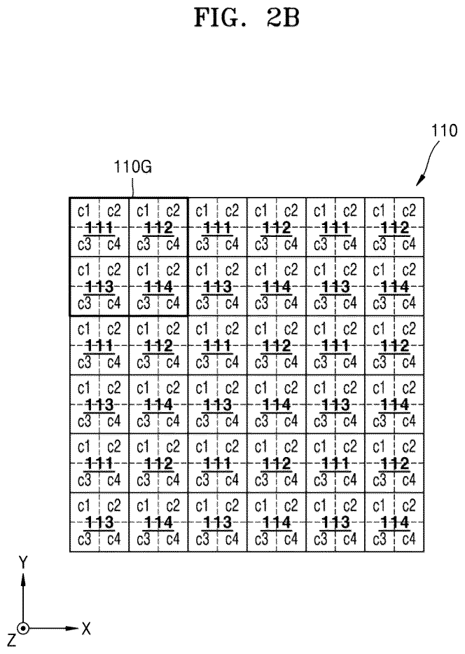

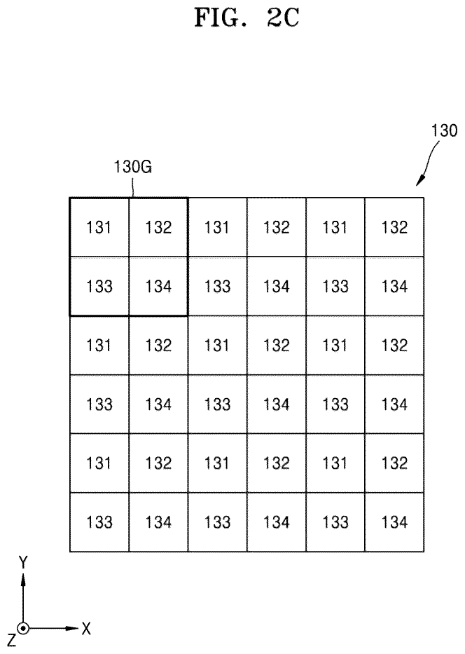

FIG. 2A is a plan view showing a color arrangement corresponding to a pixel array of an image sensor according to an embodiment, and FIGS. 2B and 2C illustrate a sensor substrate and a color separation lens array provided in the pixel array of the image sensor according to an embodiment.

The color arrangement shown in FIG. 2A is an array of a Bayer pattern which may be adopted in a general image sensor. As shown in the drawings, one unit pattern includes four quadrant regions, and first to fourth quadrants may be blue B, green G, red R, and green G, respectively. The unit patterns may be repeatedly two-dimensionally arranged in a first direction (e.g., an X direction) and a second direction (e.g., a Y direction). For such a color arrangement, in a unit pattern having a 2×2 array, two green pixels may be placed in one diagonal direction and one blue pixel and one red pixel are placed in the other diagonal direction. For example, a first row in which the plurality of green pixels and the plurality of blue pixels are alternatingly arranged in the first direction and a second row in which the plurality of red pixels and the plurality of green pixels are alternatingly arranged in the first direction may be repetitively arranged in the second direction.

The color arrangement of FIG. 2A is an example and not limited thereto. For example, in some embodiments a CYGM arrangement may be used which includes magenta, cyan, yellow, and green in one unit pattern, or a RGBW arrangement may be used which includes green, red, blue, and white in one unit pattern. In addition, the unit pattern may be implemented as a 3×2 array, and the pixels of the pixel array 1100 may be arranged in various ways according to the color characteristics of the image sensor 1000. In the description below, the pixel array 1100 of the image sensor 1000 is described as having a Bayer pattern, but embodiments are not limited thereto, and embodiments may be applied to a pixel array other than the Bayer pattern.

The pixel array 1100 of the image sensor 1000 may be provided with a sensor substrate 110 having a pixel arrangement corresponding to the above color arrangement and a color separation lens array 130 to condense light corresponding to a specific pixel. FIGS. 2B and 2C are plan views showing the sensor substrate 110 and the color separation lens array 130.

Referring to FIG. 2B, the sensor substrate 110 may include a plurality of pixels to detect incident light. The sensor substrate 110 may include a plurality of unit pixel groups 110G. The unit pixel group 110G may include a first pixel 111, a second pixel 112, a third pixel 113, and a fourth pixel 114 each configured to convert incident light into an electrical signal to generate an image signal. The unit pixel group 110G may have a pixel arrangement in the form of a Bayer pattern. The pixel arrangement of the sensor substrate 110 may be used for separating incident light into a unit pattern, such as a Bayer pattern as shown in FIG. 2A, and for sensing the incident light. For example, the first pixel 111 and the fourth pixel 114 may be a green pixel configured to detect green light, the second pixel 112 may be a blue pixel configured to detect blue light, and the third pixel 113 may be a red pixel configured to detect red light. Hereinafter, examples are described in which the pixel arrangement of the image sensor may be the same as the pixel arrangement of the sensor substrate. In addition, the first pixel 111 and the fourth pixel 114 may be referred to as a first green pixel and a second green pixel, respectively, and the second pixel 112 and the third pixel 113 may be referred to as the blue pixel and the red pixel, respectively. However, the above description is for convenience of explanation, and embodiments are not limited thereto.

Each of the first to fourth pixels 111, 112, 113, and 114 may include a plurality of light detection cells, for example light detection cell c1, light detection cell c2, light detection cell c3, and light detection cell c4, which may be used to independently detect incident light. For example, the first to fourth pixels 111, 112, 113, and 114 may each include first to fourth light detection cells c1, c2, c3, and c4. The first to fourth light detection cells c1, c2, c3, and c4 may be arranged two-dimensionally in the first direction (e.g., the X direction) and the second direction (e.g., the Y direction). For example, in each of the first to fourth pixels 111, 112, 113, and 114, the first to fourth light detection cells c1, c2, c3, and c4 may be arranged in a 2×2 array.

Although FIG. 2B illustrates an example in which the first to fourth pixels 111, 112, 113, and 114 each include four light detection cells, embodiments are not limited thereto, and in some embodiments each of the first to fourth pixels 111, 112, 113, and 114 may include one light detection cell or two light detection cells, or four or more independent light detection cells may be clustered and arranged two-dimensionally. For example, each of the first to fourth pixels 111, 112, 113, and 114 may include a plurality of independent light detection cells arranged in a cluster in a 3×3 array or a 4×4 array. Hereinafter, for convenience of explanation, examples in which each of the first to fourth pixels 111, 112, 113, and 114 includes light detection cells arranged in a 2×2 array are described.

In an embodiment, some of the plurality of pixels including a plurality of light detection cells that detect light of the same color may be used as an autofocus pixel. In an autofocus pixel, an autofocus signal may be obtained based on the difference between output signals of adjacent light detection cells. For example, an autofocus signal of the first direction (e.g., the X direction) may be generated based on the difference between an output signal of the first light detection cell c1 and an output signal of the second light detection cell c2, the difference between an output signal of the third light detection cell c3 and the fourth light detection cell c4, or the difference between the sum of the output signal of the first light detection cell c1 and the third light detection cell c3 and the sum of the output signal of the second light detection cell c2 and the fourth light detection cell c4. In addition, an autofocus signal of the second direction (e.g., the Y direction) may be generated based on the difference between the output signal of the first light detection cell c1 and the third light detection cell c3, the difference between the output signal of the second light detection cell c2 and the fourth light detection cell c4, or the difference between the sum of the output signal of the first light detection cell c1 and the second light detection cell c2 and the sum of the output signal of the second light detection cell c2 and the fourth light detection cell c4. The autofocusing (AF) performance using the autofocus signal may depend on details of nanoposts provided in the color separation lens array 130. The larger the autofocus contrast, the greater the sensitivity of the autofocus, thereby improving the AF performance.

Methods of obtaining a general image signal may include a sum mode and a full mode. In the sum mode, the image signal may be obtained by combining the output signals of the first to fourth light detection cells c1, c2, c3, and c4. For example, a first green image signal may be generated by combining the first to fourth light detection cells c1, c2, c3, and c4 of the first pixel 111, a blue image signal may be generated by combining the output signals of the first to fourth light detection cells c1, c2, c3, and c4 of the second pixel 112, a red image signal may be generated by combining the first to fourth light detection cells c1, c2, c3, and c4 of the third pixel 113, and a second green image signal may be generated by combining the output signals of the first to fourth light detection cells c1, c2, c3, and c4 of the fourth pixel 114. In the full mode, the output signal may be obtained by operating each of first to fourth light detection cells c1, c2, c3, and c4 as independent pixels. In this case, an image of high resolution may be obtained.

Referring to FIG. 2C, the color separation lens array 130 may include a plurality of pixel corresponding areas, and nanoposts may be provided in each area. The area division of the color separation lens array 130 and the shape and arrangement of the nanoposts provided in each area may be adopted to separate incident light according to the wavelength and be condensed in pixels facing each other to form a phase profile. The description below is based on the color separation in the visible light band, but embodiments are not limited thereto, and the wavelength band may be extended to the scope of visible light to infrared (IR) rays, or various other ranges.

The color separation lens array 130 may include a plurality of pixel corresponding groups 130G respectively corresponding to the plurality of unit pixel groups 110G of the sensor substrate 110 shown in FIG. 2B. The pixel corresponding group 130G may include a first pixel corresponding area 131, which may correspond to the first pixel 111, a second pixel corresponding area 132, which may correspond to the second pixel 112, a third pixel corresponding area 133, which may correspond to the third pixel 113, and a fourth pixel corresponding area 134, which may correspond to the fourth pixel 114. The first to fourth pixel corresponding areas 131, 132, 133, and 134 may each include a plurality of nanoposts. The plurality of nanoposts may be configured to separate incident light according to wavelengths and condense the incident light in the first to fourth pixels 111, 112, 113, and 114. As described with reference to FIG. 2B, the first pixel 111 and the fourth pixel 114 may respectively be the first green pixel and the second green pixel, the second pixel 112 may be a blue pixel, and the third pixel 113 may be a red pixel. In this case, the first pixel corresponding area 131 and the fourth pixel corresponding area 134 may respectively be referred to as a first green pixel corresponding area and a second green pixel corresponding area, the second pixel corresponding area 132 may be referred to as a blue pixel corresponding area, and the third pixel corresponding area 133 may be referred to as a red pixel corresponding area.

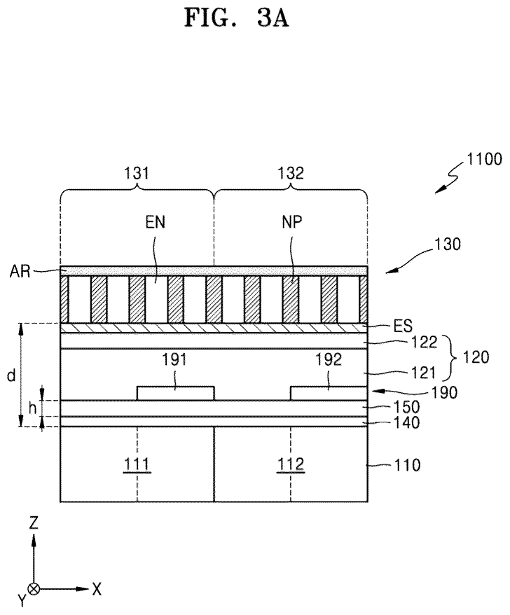

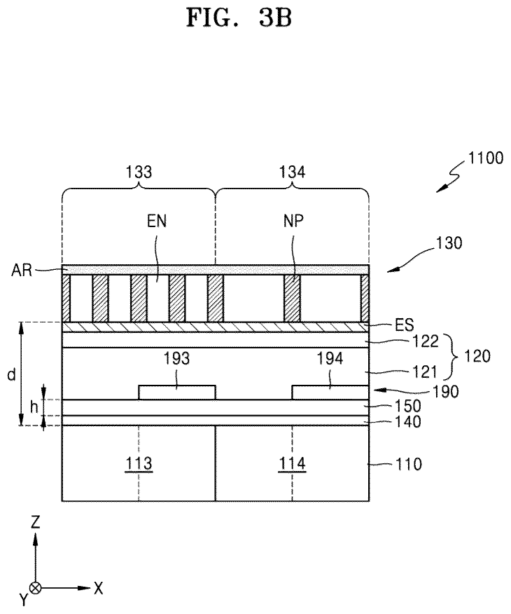

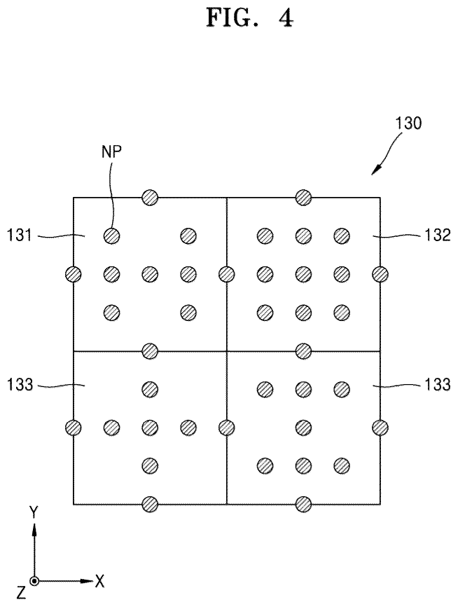

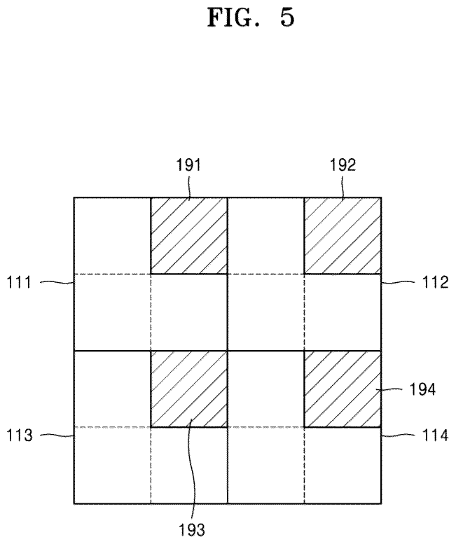

FIGS. 3A and 3B are cross-sectional views of pixel arrays from different cross-sections, according to an embodiment, FIG. 4 is a plan view of an example of an array of nanoposts provided in the color separation lens array of the pixel array according to an embodiment, and FIG. 5 is a plan view of an array of first to fourth spectroscopic filters of the spectroscopic filter layer provided in the pixel array with respect to the sensor substrate, according to an embodiment.

Referring to FIGS. 3A and 3B, the pixel array 1100 of the image sensor 1000 may include the sensor substrate 110, the color separation lens array 130 arranged above and apart from the sensor substrate 110, an organic photoelectric conversion layer 150 arranged between the sensor substrate 110 and the color separation lens array 130, and a spectroscopic filter layer 190 arranged between the organic photoelectric conversion layer 150 and the color separation lens array 130. An interlayer 140 may be arranged between the sensor substrate 110 and the organic photoelectric conversion layer 150.

As described above with reference to FIG. 2B, the sensor substrate 110 may include the first pixel 111, the second pixel 112, the third pixel 113, and the fourth pixel 114 configured to sense light, and the first pixel 111, the second pixel 112, the third pixel 113, and the fourth pixel 114 may each include a plurality of light detection cells. In some embodiments, a separator for separating cells may be further formed in a boundary between cells. The light detection cell may absorb incident light and generate an electrical signal, and may be or may include an inorganic sensor. The light detection cell may include an inorganic photoelectric conversion material, for example, a photodiode including inorganic materials. The light detection cell may include, for example, a silicon photodiode.

The color separation lens array 130 may include the first pixel corresponding area 131 and the fourth pixel corresponding area 134 respectively corresponding to the first pixel 111 and the fourth pixel 114 in which green light is condensed. In addition, the color separation lens array 130 may further include the second pixel corresponding area 132 corresponding to the second pixel 112 in which blue light is condensed, and the third pixel corresponding area 133 corresponding to the third pixel 113 in which red light is condensed.

The color separation lens array 130 may include a plurality of nanoposts NP and a surrounding material EN arranged around the plurality of nanoposts NP. The surrounding material EN may include a material having a different refractive index from the plurality of nanoposts NP, and may therefore form a refractive index difference with the nanoposts NP.

The plurality of nanoposts NP may be divided and arranged in the first to fourth pixel corresponding areas 131, 132, 133, and 134. For example, the plurality of nanoposts NP may be arranged in each of the first to fourth pixel corresponding areas 131, 132, 133, and 134, and based on the shape and arrangement of the nanoposts NP included in each of the first to fourth pixel corresponding areas 131, 132, 133, and 134, incident light may be separated according to the wavelengths and may be condensed in the first to fourth pixels 111, 112, 113, and 114.

Because the refractive index of a material may appear differently according to the wavelength of light, the color separation lens array 130 may provide different phase profiles for different wavelength light. For example, even the same material may have a different refractive index according to the wavelength of light reacting to the material and the phase delay of light transmitting through the material differs according to the wavelength, thereby causing different phase profiles to be formed according to the wavelengths. For example, the refractive index of first wavelength light of the first pixel corresponding area 131 may be different from the refractive index of second wavelength light of the first pixel corresponding area 131, and the phase delay of the first wavelength light transmitted through the first pixel corresponding area 131 may be different from the phase delay of the second wavelength light transmitted through the first pixel corresponding area 131. Accordingly, when the color separation lens array 130 is designed considering the above characteristics of light, different phase profiles for the first and second wavelength light may be provided.

A plurality of nanoposts NP provided in the color separation lens array 130 may be arranged in a specific rule to form different phase profiles for light of the plurality of wavelengths. Here, the rule may be applied to parameters, such as the shape of the nanoposts NP, sizes (e.g., widths and heights) of the nanoposts NP, a distance between the nanoposts NP, and the arrangement shape thereof, and these parameters may be determined according to the phase profile of each color to be implemented through the color separation lens array 130.

The nanoposts NP may have a shape dimension of a sub wavelength. Here, the sub wavelength may refer to to a wavelength that is less than a wavelength band of light to be branched. The nanopost NP may have a cylinder shape having a cross-sectional diameter of a sub-wavelength. However, the shape of the nanopost NP is not limited thereto, and in some embodiments the shape of the nanopost NP may be an elliptical pillar or a polygonal pillar. The nanoposts NP may have post shapes having a symmetrical or asymmetrical cross-sectional shape. The nanoposts NP are shown to have a constant width vertical to the height direction (e.g., a Z direction), In FIGS. 3A and 3B, a cross-section that is parallel to the height direction is illustrated as having a rectangular form, but the descriptions are only examples. For example, in some embodiments the nanoposts NP may not have constant widths in the height direction, and, for example, the shape of a cross-section parallel to the height direction may be a trapezoid shape or an inverse trapezoid shape. When incident light is visible, the diameter of the cross-section of the nanopost NP may be less than, for example, 400 nanometers (nm), 300 nm, or 200 nm. The height of the nanostructure NP may be about 500 nm to about 1,500 nm and may be greater than the width of the cross-section. The height of the nanoposts NP may be several times the sub-wavelengths to wavelengths. For example, the height of the nanoposts NP may be five times or less, four times or less, or three times or less than the central wavelength of the wavelength band in which the color separation lens array 130 is branched.

Spaces between the nanoposts NP may be filled with the surrounding materials EN that have different refractive indices from the nanoposts NP. The nanopost NP may include a material having a different refractive index from that of the surrounding material EN. The nanopost NP may include a c-Si, p-Si, a-Si and III-V compound semiconductor (GaP, GaN, GaAs etc.), SiC, TiO₂, SiN, and/or a combination thereof. A nanopost NP having a difference in the refractive index with that of the surrounding material EN may change the phase of light transmitting through the nanopost NP. This may be caused by phase delay that occurs due to the shape dimension of the sub wavelength of the nanoposts NP, and the degree at which the phase is delayed may be determined by a detailed shape dimension and arrangement shape of the nanoposts NP.

The surrounding material EN of the nanopost NP may include dielectric materials with a relatively low refractive index and a relatively low absorption rate in the visible light band, than the nanopost NP. The surrounding material EN may be, for example, siloxane-based spin on glass (SOG), SiO₂, Al₂O₃, or air.

The material of the nanopost NP and the surrounding material EN is an example, and a change in which the surrounding material EN includes a material having a high refractive index and the nanopost NP includes a material having a low refractive index may be made.

The arrangement of the nanoposts NP in the first to fourth pixel corresponding areas 131, 132, 133, and 134 illustrated in FIG. 4 is an example, and may be changed in various ways according to embodiments. The arrangement of the nanoposts NP may be variously determined according to the phase profile for each color to be implemented through the color separation lens array 130. For example, the arrangement of the nanoposts NP may be variously determined in order to implement the phase profile by which the wavelengths of incident light are separated and condensed on the first to fourth pixels 111, 112, 113, and 114 corresponding to the wavelengths. Although FIGS. 3A and 3B show the nanoposts NPs as being arranged in a single layer, embodiments are not limited thereto, and in some embodiments the nanoposts NP may be arranged in two or more layers.

In the pixel array 1100 according to an embodiment, the organic photoelectric conversion layer 150 disposed between the sensor substrate 110 and the color separation lens array 130 may be provided to increase the sensing sensitivity.

The organic photoelectric conversion layer 150 may have a multi-exciton generation function, for example a function of generating excitons by absorbing photons. The excitons generated in the organic photoelectric conversion layer 150 may move towards the sensor substrate 110, for example to an inorganic photodiode included in the first to four pixels 111, 112, 113, and 114 of the sensor substrate 110, thereby improving the sensing efficiency of the image sensor 1000.

The organic photoelectric conversion layer 150 may be or may include a singlet fission material, from among organic materials, using a triplet excited state using a triplet excited state, and may include a material in which a multiple exciton generation (MEG) is expressed. In a singlet fission material, a singlet exciton (a charge-hole pair) generated by absorbing light may change into two triplet exciton pairs and the MEG may refer to absorbing one photon having a bandgap energy or more to generate a plurality of excitons. The organic photoelectric conversion layer 150 may include a singlet fission material to absorb incident light and generate a great amount of excitons, and a signal amplified due to the generation of the great amount of excitons may be transmitted to the sensor substrate 110.

The organic photoelectric conversion layer 150 may include, for example, polyacene, rylene, rubrene, biradicaloid, or a combination thereof. Polyacene may include anthracene, tetracene, pentacene, or a combination thereof. Rylene may include perylene, terylene, or a combination thereof. Byradicaloid may include benzofuran. A thickness h of the organic photoelectric conversion layer 150 may be about 100 nm or less. The thickness h of the organic photoelectric conversion layer 150 may be about 20 nm or more and 100 nm or less. The thickness h of the organic photoelectric conversion layer 150 may be near 30 nm, for example, about 20 nm or more and about 40 nm or less. However, embodiments are not limited thereto.

The organic photoelectric conversion layer 150 may be formed as one layer entirely facing the first to fourth pixels 111, 112, 113, and 114, as shown in FIGS. 3A and 3B. The organic photoelectric conversion layer 150 formed as described above may have a constant thickness h in the entire area facing the first to fourth pixels 111, 112, 113, and 114. However, this is an example, and in some embodiments, the organic photoelectric conversion layer 150 may include cells having different thicknesses according to the color of the pixel facing the organic photoelectric conversion layer 150.

An interlayer 140 may further be arranged between the sensor substrate 110 and the organic photoelectric conversion layer 150. The interlayer 140 may prevent recombination of the charge-hole pair in the surface of the sensor substrate 110, and may be provided such that the charge generated in the organic photoelectric conversion layer 150 may be easily transmitted to the first to fourth pixels 111, 112, 113, and 114 of the sensor substrate 110. The interlayer 140 may, for example, include at least one material from silicon oxide (SiOₓ), silicon nitride (SiNₓ), aluminum oxide (Al₂O₃), titanium oxide (TiOₓ), hafnium oxide (HfOₓ), hafnium nitride (HfOₓN_{y}), germanium oxide (GeOₓ), and gallium oxide (GaOₓ). Here, x and y denote real numbers greater than 0. The thickness of the interlayer 140 may be less than 10 nm. The thickness of the interlayer 140 may be about 0.1 nm or more and about 10 nm or less. The thickness of the interlayer 140 may be near 1 nm, for example, about 0.5 nm or more and about 2 nm or less. However, embodiments are not limited thereto.

The sum of the thickness of the interlayer 140 and the organic photoelectric conversion layer 150 may be about 20 nm or more and about 100 nm or less.

Because the pixel array 1100 according to an embodiment may be color separated by the color separation lens array 130, color light may be distinguished and sensed without a separate color filter. Thus, optical loss due to the organic color filter of the prior art may not occur.

The pixel array 1100 according to an embodiment may be provided with a spectroscopic filter layer 190 to further subdivide the wavelength band separated by the color separation lens array 130. The spectroscopic filter layer 190 may be arranged on the organic photoelectric conversion layer 150 and the color separation lens array 130. The spectroscopic filter layer 190 may include a first spectroscopic filter 191 facing the first pixel 111, a second spectroscopic filter 192 facing the second pixel 112, a third spectroscopic filter 193 facing the third pixel 113, and a fourth spectroscopic filter 194 facing the fourth pixel 114 . . . . The first to fourth spectroscopic filters 191, 192, 193, and 194 may have different transmission spectrums according to the color of the pixel facing the first to fourth spectroscopic filters 191, 192, 193, and 194. The first to fourth spectroscopic filters 191, 192, 193, and 194 may be or may include filters that subdivide spectrums of green light, blue light, red light, and green light, respectively.

The first to fourth spectroscopic filters 191, 192, 193, and 194 may include an inorganic material. Each of the first to fourth spectroscopic filters 191, 192, 193, and 194 may be a Fabry-Perot resonator-based filter or a nanostructure-based filter.

The first spectroscopic filter 191 may face one of the four light detection cells provided in the first pixel 111. The second spectroscopic filter 192 may face one of the four light detection cells provided in the second pixel 112. The third spectroscopic filter 193 may face one of the four light detection cells provided in the third pixel 113. The fourth spectroscopic filter 194 may face one of the four light detection cells provided in the fourth pixel 114. Relative positions of the light detection cells in the corresponding pixels respectively facing the first to fourth spectroscopic filters 191, 192, 192, and 194 may be the same.

The relative size and arrangement of the first to fourth spectroscopic filters 191, 192, 193, and 194 with respect to the first to fourth pixels 111, 112, 113, and 114 respectively facing the first to fourth spectroscopic filters 191, 192, 193, 194 are examples and not limited thereto. For example, the first to fourth spectroscopic filters 191, 192, 193, and 194 may face two or three light detection cells from among the four light detection cells provided in the first to fourth pixels 111, 112, 113, and 114 respectively facing the first to fourth spectroscopic filters 191, 192, 193, and 194. As another example, each of the first to fourth pixels 111, 112, 113, and 114 may include two light detection cells, and the first to fourth spectroscopic filters 191, 192, 193, and 194 may face one of the light detection cells included in the first to fourth pixels 111, 112, 113, and 114. As yet another example, each of the first to fourth pixels 111, 112, 113, and 114 may include more than four light detection cells, and the first to fourth spectroscopic filters 191, 192, 193, and 194 may respectively face one or more light detection cells. As a further example, first to fourth spectroscopic filters 191, 192, 193, and 194 may each face all of the light detection cells included in the first to fourth pixels 111, 112, 113, and 114.

The size of the first to fourth spectroscopic filters 191, 192, 193, and 194, for example, the size of the cross-section facing the sensor substrate 110, may be determined in consideration of light efficiency and image processing efficiency. The first to fourth spectroscopic filters 191, 192, 193, and 194 may not cause the same amount of light loss as the organic color filters, but some light loss may occur due to the first to fourth spectroscopic filters 191, 192, 193, and 194. Thus, a method of reducing the number or size of the first to fourth spectroscopic filters 191, 192, 193, and 194 and instead, improving color accuracy through image signal processing may be used.

A transparent spacer layer 120 may be arranged between the sensor substrate 110 and the color separation lens array 130. The spacer layer 120 may have a thickness d that supports the color separation lens array 130 and satisfies a distance requirement between the sensor substrate 110 and the color separation lens array 130, for example between an upper surface of the sensor substrate 110 and a lower surface of the color separation lens array 130. The thickness d of the spacer layer 120 may be about 500 nm or more and about 1000 nm or less. Because the thickness d of the spacer layer 120 may be determined according to an optical distance requirement between the upper surface of the sensor substrate 110 and the lower surface of the color separation lens array 130, the optical distance requirement being related to the focal distance of the color separation lens array 130, and the thickness d of the spacer layer may vary according to the refractive indices and thicknesses of the organic photoelectric conversion layer 150, the spectroscopic filter layer 190, and the interlayer 140 between the sensor substrate 110 and the color separation lens array 130 and the refractive index of the spacer layer 120.

The spacer layer 120 may include a material that is transparent with respect to visible light, for example, SiO₂, siloxane-based spin on glass (SOG), etc., which are dielectric materials having a lower refractive index than the nanopost NP and a low absorption rate in a visible light band. The spacer layer 120 may include a material having a lower refractive index than the nanopost NP or may include the same material as the surrounding material EN.

The spacer layer 120 may include a planarization layer 121 and an encapsulation layer 122.

The planarization layer 121 may include a material appropriate for flattening a surface that is not flat formed by the organic photoelectric conversion layer 150 and the spectroscopic filter layer 190. The planarization layer 121 may include an organic polymer material. The organic polymer material may have transparent characteristics with respect to visible light. For example, the planarization layer 121 may include at least one organic polymer material of epoxy resin, polyimide, polycarbonate, polyacrylate, and polymethyl methacrylate (PMMA).

The encapsulation layer 122 may act as a protective layer to prevent damage to the planarization layer 121 formed of an organic polymer material in a high temperature process of forming the color separation lens array 130 on the planarization layer 121. The encapsulation layer 122 may also act as a spread prevention layer. To this end, the encapsulation layer 122 may include an inorganic material. The inorganic material of the encapsulation layer 122 may be formed at a temperature lower than a process temperature for forming the color separation lens array 130, and may include a transparent material with respect to visible light. In addition, the refractive index of the encapsulation layer 122 needs to be similar to the refractive index of the planarization layer 121 such that reflection loss at an interface between the planarization layer 121 and the encapsulation layer 122 is reduced. For example, the difference between the refractive index of the planarization layer 121 and the refractive index of the encapsulation layer 122 may be within +20% of the refractive index of the planarization layer 121. For example, the encapsulation layer 122 may include at least one inorganic material from SiO₂, SiN, and SiON.

Although FIGS. 3A and 3B show the spacer layer 120 as being separated into the planarization layer 121 and the encapsulation layer 122, this is only an example, and embodiments are not limited thereto. For example, in some embodiments the spacer layer 120 may be formed of a single layer including a dielectric material having a lower refractive index than the nanopost NP and having a low absorption rate in a visible light band.

An etch stop layer ES may be arranged between the spacer layer 120 and the color separation lens array 130. The etch stop layer ES may be provided to protect the spacer layer 120, which may be a lower structure of the color separation lens array 130, in the manufacturing process of the color separation lens array 130. When the color separation lens array 130 is manufactured on the spacer layer 120, after depositing the material layer to be formed as the surrounding material EN, a process of etching the material layer by a predetermined depth is performed so as to form the nanopost NP. In this case, the material layer may be etched more than a desired depth, thereby damaging the spacer layer 120 and, when the thickness of the spacer layer 120 does not meet the distance requirement between the color separation lens array 130 and the sensor substrate 110, the color separation performance may be reduced. The etch stop layer ES may include a material having a lower etching selectivity ratio than the material layer being etched and may thus not be removed completely in the etching process and may partially remain, thereby preventing the spacer layer 120 from being damaged in the etching process. The etch stop layer ES may include HfO₂. The thickness of the etch stop layer ES may be determined in consideration of the etching depth, for example the height of the nanoposts NP, and may also be determined in consideration of an etch scatter in a process wafer. The thickness of the etch stop layer ES may be about 3 nm to about 30 nm.

An anti-reflection layer AR may be arranged on the color separation lens array 130. The anti-reflection layer AR may reduce light reflected from the upper surface of the color separation lens array 130 based on incident light, thereby improving use efficiency of light of the pixel array 1100. In other words, the anti-reflection layer AR may allow light incident on the pixel array 1100 from the outside to transmit through the color separation lens array 130 and be sensed by the sensor substrate 110 instead of being reflected on the upper surface of the color separation lens array 130. The anti-reflection layer AR may also act as a protective layer protecting the color separation lens array 130. The anti-reflection layer AR may have a structure in which one or a plurality of layers are stacked. For example, the anti-reflection layer AR may include one layer including a material that is different from a material included in the color separation lens array 130, or may include a plurality of material layers having different refractive indices.

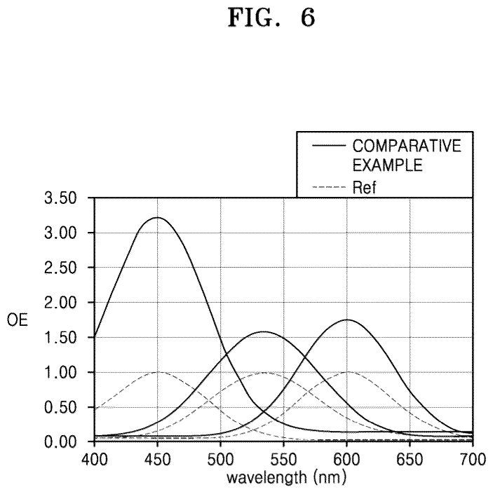

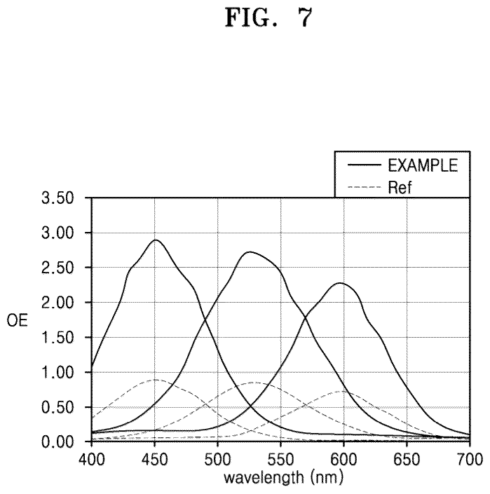

FIG. 6 is a graph showing the color separation performance of the pixel array as a comparative example, and FIG. 7 is a graph showing the color separation performance of the pixel array as an example.

The comparative example relates to an image sensor in which the color separation lens array 130 is included and the organic photoelectric conversion layer 150 and the spectroscopic filter layer 190 are not included. The dashed lines marked as Ref relates to an image sensor which does not include the color separation lens array 130.

In the graph of FIG. 6, the light efficiency of the red wavelength band and the green wavelength band are lower than the light efficiency of the blue wavelength band. In addition, an overlap between the color spectra may increase, thereby causing the accuracy of the final image to be lowered.

In comparison with FIG. 6, FIG. 7 illustrates an example in which, by further including the organic photoelectric conversion layer 150 and the spectroscopic filter layer 190, the light sensing sensitivity is improved, and thus, the light efficiency of the red wavelength band and the green wavelength band may be increased. For example, the sensitivity between the color spectrums may be balanced. In addition, the color accuracy of the final image may be improved by an image signal processing using a signal of a subpixel including the spectroscopic filter layer.

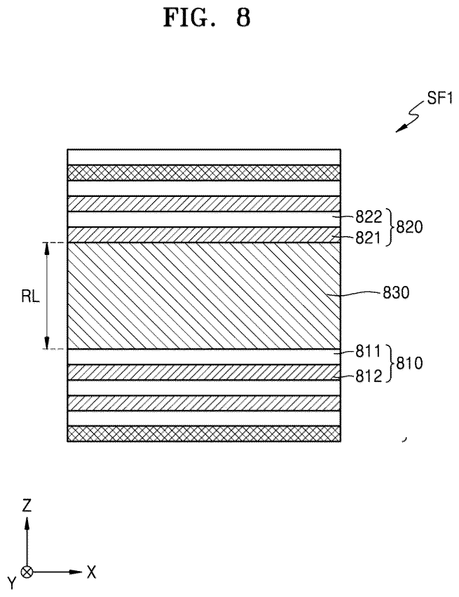

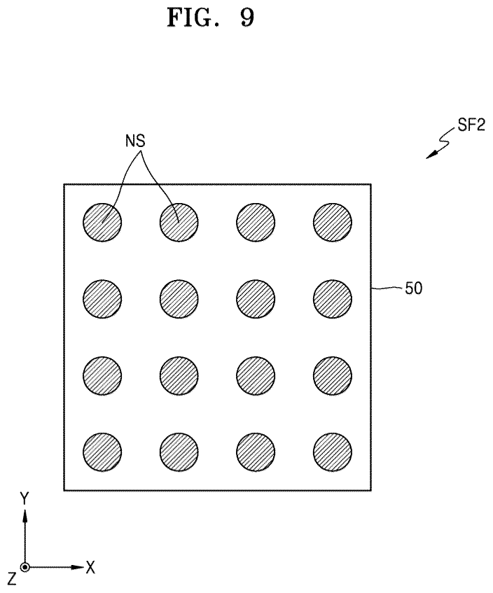

FIG. 8 is a cross-sectional view and a plan view showing an example of a structure of inorganic material-based spectroscopic filters that may be provided in the pixel array, and FIG. 9 is a corresponding plan view, according to an embodiment.

The spectroscopic filter SF1 of FIG. 8 may be a Fabry-Perot resonator filter.

The spectroscopic filter SF1 may include a first reflector 810, a second reflector 820, and a cavity layer 30 arranged between the first reflector 810 and the second reflector 820.

The cavity layer 830, which may be a resonant layer, may include a semiconductor material or a dielectric material having a predetermined refractive index. For example, the cavity layer 30 may include silicon or silicon oxide. However, embodiments are not limited thereto, and in some embodiments the cavity layer 30 may include various materials according to design conditions, such as the wavelength of incident light.

The first reflector 810 and the second reflector 820 on the upper surface and the lower surface of the cavity layer 830 may each be a distributed Bragg reflector (DBR).

The first reflector 810 has a structure in which two types of material layers 811 and 812 having different refractive indices are alternatingly arranged. The material layers 811 and 812 may include, for example, two materials selected from titanium oxide, silicon oxide, hafnium oxide, silicon, and silicon nitride. The second reflector 820 has a structure in which two types of material layers 821 and 822 having different refractive indices are alternatingly arranged. The material layers 821 and 822 may include two materials selected from titanium oxide, silicon oxide, hafnium oxide, silicon, and silicon nitride. The number and arrangement of the material layers 811, 812, 821, and 822 may vary. The first reflector 810 and the second reflector 820 may have independent configurations.

The resonance wavelength may be determined according to the effective refractive index and thickness RL of the cavity layer 830 and, according to the detailed configuration of the first reflector 810 and the second reflector 820, the full width at half maximum (FWHM) of the transmission spectrum of the spectroscopic filter SF1 may be controlled. The FWHM of the transmission spectrum of the spectroscopic filter SF1 may be less than the FWHM of the color spectrum of the color separation lens array 130. The thickness RL of the cavity layer 830 provided in the spectroscopic filter SF1 may be briefly referred to as the resonator thickness of the spectroscopic filter SF1.

The spectroscopic filter SF1 may be applied to each of the first to fourth spectroscopic filters 191, 192, 193, and 194 described above. When the spectroscopic filter SF1 is applied to the first to fourth spectroscopic filters 191, 192, 193, and 194, the resonator thicknesses of the first to fourth spectroscopic filters 191, 192, 193, and 194 may become different from each other according to the color of the pixels facing the first to fourth spectroscopic filters 191, 192, 193, and 194. In addition, according to the relative position of the first to fourth spectroscopic filters 191, 192, 193, and 194 in the image sensor 1000, for example according to the chief ray angle (CRA), the details of the resonator thickness or the design of the first and second reflectors 810 and 820 may change. In other words, the detailed structures of two filters facing the pixels with the same color, for example, two first spectroscopic filters 191 with different CRA positions, may be different from each other.

A spectroscopic filter SF2 of FIG. 9 may be a band transmission filter based on a nanostructure NS.

The spectroscopic filter SF2 may include a plurality of nanostructures NS and may further include a support layer 50 configured to support the plurality of nanostructure NS. The nanostructure NS may include a material having a refractive index that is greater than a refractive index of the surrounding material. The nanostructure NS may include poly-Si, for example, and may include various other inorganic materials. The plurality of nanostructures NS may include a shape dimension of a sub wavelength. The nanostructure NS may have a cylinder shape. However, embodiments are not limited thereto, and in some embodiments the nanostructure NS may have an elliptical pillar shape or a polygonal pillar shape. The above description in which all the plurality of nanostructures NS have the same size is an example, and embodiments are not limited thereto. The transmission wavelength band may be controlled according to the shape, size, and arrangement rules of the plurality of nanostructures NS.

The spectroscopic filter SF2 may be applied to the first to fourth spectroscopic filters 191, 192, 193, and 194 described above. In this case, the details of the nanostructure NS provided in the spectroscopic filter SF2 may change according to the pixel facing the first to fourth spectroscopic filters 191, 192, 193, and 194. For example, at least one of the shape, size, and arrangement rule of plurality of nanostructures NS may be different such that the transmittance wavelength band may be adjusted.

The plurality of nanostructures NS provided in the first to fourth spectroscopic filters 191, 192, 193, and 194 may be arranged by the same rule according to the color of the pixel facing the nanostructures NS, and may only differ in size. For example, the size or height of the cross sections of the nanostructures NS may be different from each other. In addition, according to the relative position, for example the CRA, of the first to fourth spectroscopic filters 191, 192, 193, and 194 in the image sensor 1000, the details of the nanostructure NS design may change. In other words, the detailed structures of two filters facing the pixels with the same color, for example, two first spectroscopic filters 191 with different CRA positions, may be different from each other.

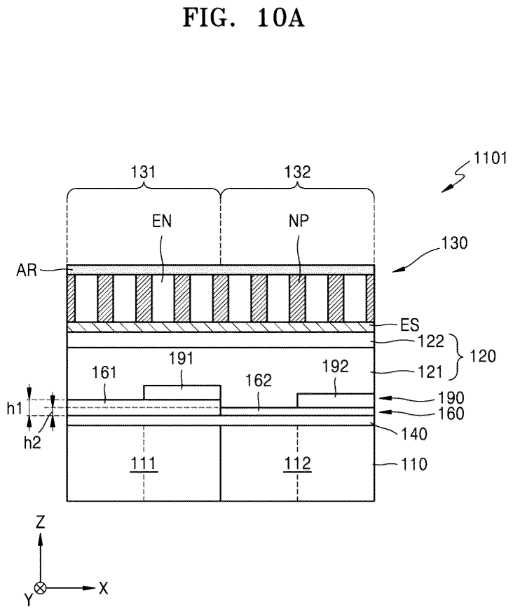

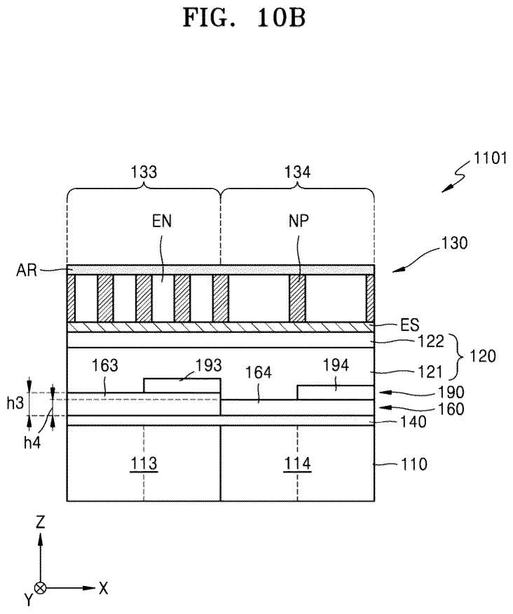

FIGS. 10A and 10B are cross-sectional views showing a pixel array 1101 according to other embodiments.

In the pixel array 1101 shown in FIGS. 10A and 10B, the organic photoelectric conversion layer 160 may include a plurality of cells, for example cell 161 facing the first pixel 111, cell 162 facing the second pixel 112, cell 163 facing the third pixel 113, and cell 164 facing the fourth cell 114. The cells 161, 162, 163, and 164 may include the organic photoelectric materials exemplified as the materials of the organic photoelectric conversion layer 150 but may have different thicknesses according to the color of a pixel facing each of the cells 161, 162, 163, and 164.

Thicknesses h1 and h4 of the cells 161 and 164 facing the first pixel 111 and the fourth pixel 114 may be the same.

The thickness h2 of the cell 162 facing the second pixel 112 may be equal to or less than h1. The thickness h2 may be less than the thickness h1, and the thickness h3 may be the same as the thickness h1. For example, the thicknesses of the cells 161, 163, and 164 respectively facing the first pixel 111, the third pixel 113, and the fourth pixel 114 may all be the same, and the thickness of the cell 162 facing the second pixel 112 may be less than the thicknesses of the cells 161, 163, and 164. The above thicknesses may be set considering that the light efficiency of red light and green light are low in the graph of FIG. 6. The thickness of the cells 161, 163, and 164 facing the third pixel 113 (e.g., the red pixel) and the first and fourth pixels 111 and 114 (e.g., the green pixels) may be greater than the thickness of the cell 162 such that the efficiency of red light and green light is increased. In some embodiments, h2 may be 0. For example, the organic photoelectric material of the organic photoelectric conversion layer 150 may be a pattern arranged only in positions facing the first and fourth pixels 111 and 114 and the third pixel 113.

The thickness h3 of the cell 163 facing the third pixel 113 may be greater than the thickness h2 of the cell 162 facing the second pixel 112. and may be greater than or less than the thickness h1 of the cell 161 facing the first pixel 111.

The cells 161, 162, 163, and 164 respectively facing the first to fourth pixels 111, 112, 113, and 114 may include different materials, according to the color of the pixels facing the cells 161, 162, 163, and 164. The cells 161, 162, 163, and 164 may include the materials exemplified as the materials of the organic photoelectric conversion layer 150, but different materials may be applied according to the color of the pixels facing the cells 161, 162, 163, and 164.

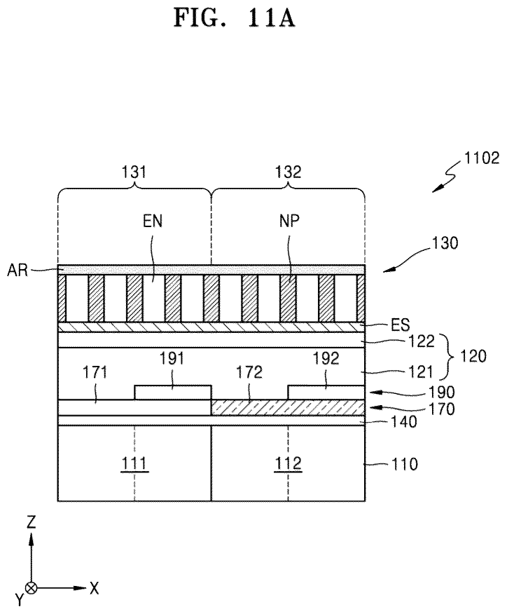

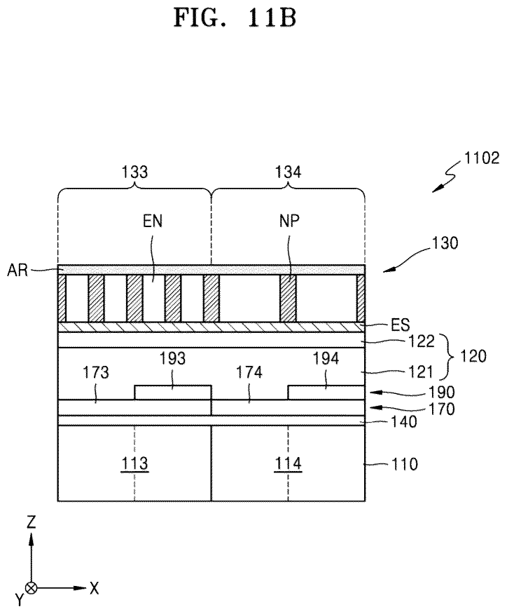

FIGS. 11A and 11B are cross-sectional views showing a pixel array 1102 according to other embodiments.

In the pixel array 1102 shown in FIGS. 11A and 11B, the organic photoelectric conversion layer 160 may include a plurality of cells, for example cell 171 facing the first pixel 111, cell 172 facing the second pixel 112, cell 173 facing the third pixel 113, and cell 174 facing the fourth cell 114. The cells 171, 173, and 174 facing the first, third and fourth pixels 111, 113, and 114 may include organic photoelectric materials, and the cell 172 facing the second pixel 112 may not include an organic photoelectric material. For example, the cell 172 may be a dummy cell, and the organic photoelectric material included in the organic photoelectric conversion layer 170 may be substantially identical such that it is arranged only in positions facing the first pixel 111, the third pixel 113, and the fourth pixel 114. The cell 172 may be made of the same material as the spacer layer 120, for example. The thicknesses of the cells 171, 173, and 174 may be the same as each other, or different from each other.

The cells 171, 172, 173, and 174 respectively facing the first, third, and fourth pixels 111, 113, and 114 may include different materials, according to the color of the pixels facing the cells 171, 172, 173, and 174. The cells 171, 172, and 174 may include the materials similar to the materials of the organic photoelectric conversion layer 150, but different materials may be applied according to a color of a pixel facing each of the cells 171, 173, and 174.

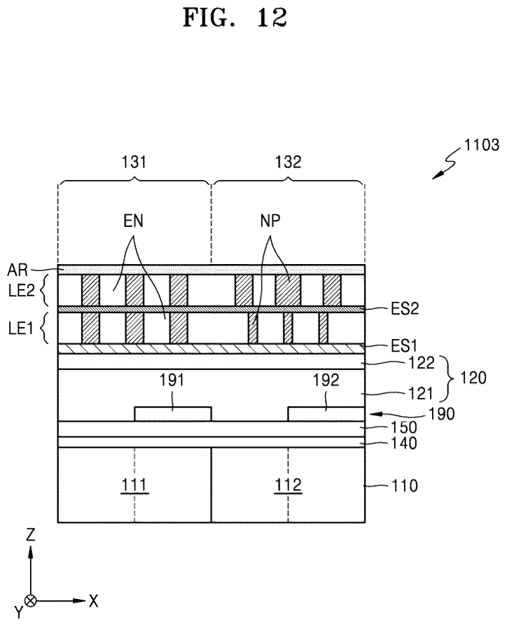

FIG. 12 is a cross-sectional view showing a pixel array 1103 according to an embodiment.

The pixel array 1103 of the embodiment may differ from embodiments described above in that the nanoposts NP of the color separation lens array 130 may be stacked to form a first lens layer LE1 and a second lens layer LE2.

In FIG. 12, the pixel array 1103 is shown as a cross-section corresponding to FIG. 3A, and the organic photoelectric conversion layer 150 is shown to be formed as a single layer, as in FIG. 3A, but embodiments are not limited thereto. The organic photoelectric conversion layer 150 may be changed in the same form as the organic photoelectric conversion layers 160 and 170 of embodiments described above.

In embodiments, the pixel array 1103 may include an etch stop layer ES1, which may correspond to the etch stop layer ES described above. In addition, an etch stop layer ES2 may be arranged between the first lens layer LE1 and the second lens layer LE2. The etch stop layer ES2 may be provided to prevent damage to the first lens layer LE1 in the process of manufacturing the second lens layer LE2. When the second lens layer LE2 is formed on the first lens layer LE1, after depositing the material layer to be formed as the surrounding material EN, a process of etching the material layer by a predetermined depth is performed so as to form the nanopost NP arranged in the second lens layer LE2. In this case, the material layer may be etched more than a desired depth, thereby damaging the first lens layer LE1 and, when the height of the first lens layer LE1 does not meet the height requirement, the color separation performance may be reduced. The etch stop layer ES1 formed on the first lens layer LE1 may include a material having a lower etching selectivity ratio than the material layer being etched and may thus not be completely removed in the etching process and partially remain, thereby preventing the first lens layer LE1 from being damaged. The etch stop layer ES2 may include HfO₂. The thickness of the etch stop layer ES2 may be determined in consideration of the etching depth, for example the height of the second lens layer LE2, and may also be determined in consideration of an etch scatter in a process wafer. The thickness of the etch stop layer ES may be about 3 nm to about 30 nm.

The surrounding materials EN in the first lens layer LE1 and the second lens layer LE2 may be the same or different materials. The nanoposts NP in the first lens layer LE1 and the second lens layer LE2 may be the same or different materials.

The nanoposts NP disposed on the first lens layer LE1 and the second lens layer LE2 are illustrated as having the same height, but embodiments are not limited thereto. The nanoposts NP arranged in the first lens layer LE1 may all have the same height, and nanoposts NP arranged in the second lens layer LE2 may have the same height that is different from the height of the nanoposts NP of the first lens layer LE1. Alternatively, even in the same layer, different heights may be applied. The details of the nanopost NP may be determined in consideration of the detailed process condition together with the phase profile for color separation.

However, the above embodiments are non-limiting examples. Forming the arrangement of the nanoposts NP to be a single layer or multiple layers may be selected considering the fine tuning of performance or the manufacturing process of the color separation lens array 130

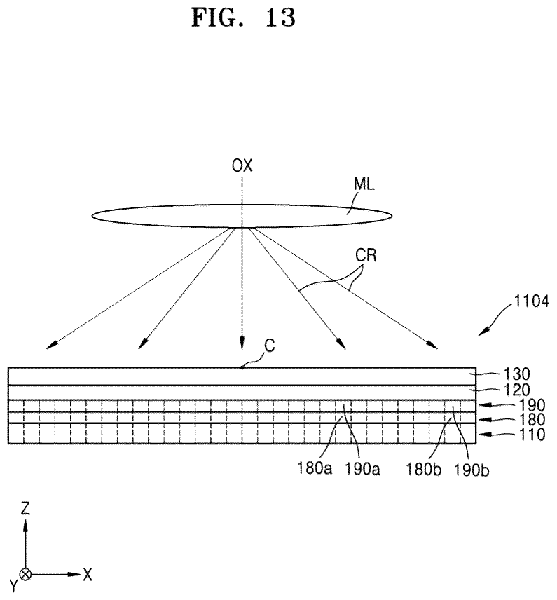

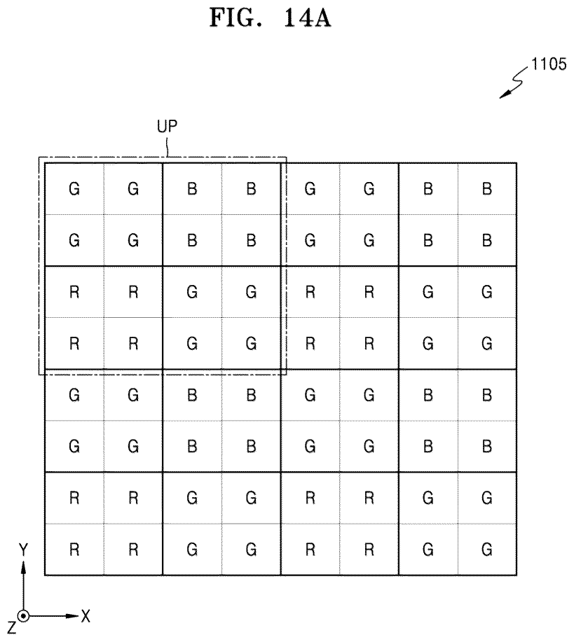

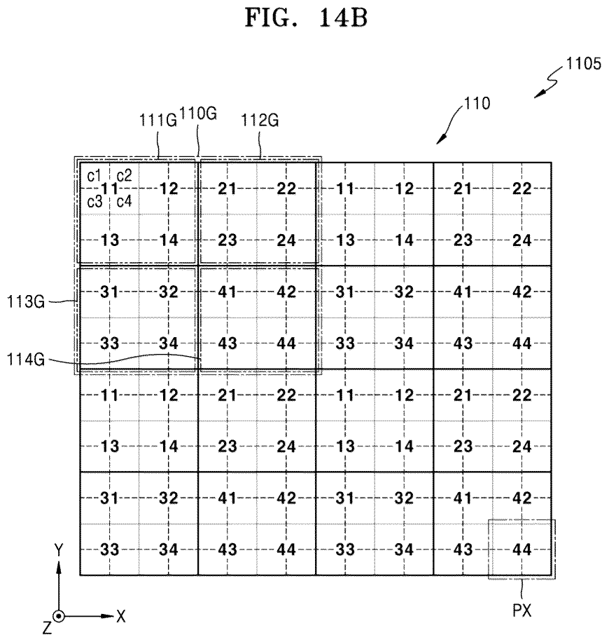

FIG. 13 is a cross-sectional view showing the pixel array and the CRA, according to an embodiment.

In the pixel array 1104 shown in FIG. 13, the organic photoelectric conversion layer 150 and/or the spectroscopic filter layer 190 may be designed considering the CRA. According to the position of the CRA, the details of the thickness of the organic photoelectric conversion layer 150 and/or the first to fourth spectroscopic filters included in the spectroscopic filter layer 190 may change.

The interior of the pixel array 1104 is not shown for convenience, but, as shown in the embodiments described above, an interior may be arranged between the sensor substrate 110 and the organic photoelectric conversion layer 150.

The pixel array 1104 of the image sensor may be used in a camera module together with a module lens ML, and light transmitted through module lens ML toward the pixel array 1104 may have a different incidence angle according to the position of the pixel array 1104. The incidence angle of light incident on the pixel array 1104 is generally referred to as the CRA. The chief ray may refer to a light beam that starts from a point of an object, is transmitted through the center of the module lens ML, and is incident on the pixel array 1104, and the CRA may refer to an angle between the chief ray CR and an optical axis OX.

The CRA of light incident on the center of the color separation lens array 130 may be 0 degrees, and as light moves away from the center, for example towards the periphery of the color separation lens array 130, the CRA of light incident on the pixel corresponding group of the position may be increased. In addition, even if the CRA is the same, the direction of the chief ray may vary according to the position of the azimuth of the pixel corresponding group. The azimuth may refer to an angle between a particular direction and a surface perpendicular to the optical axis OX, for example, an angle between the X direction and an X-Y plane.

In the arrangement of the nanostructures provided in the pixel corresponding group included in the color separation lens array 130, the size and direction of the CRA may be considered. Hereinafter, position at which CRA is 0 degrees or close to 0 degrees may be referred to as a center portion, and the remaining positions may be referred to as the peripheral portion. Positions that may be considered as the center portion are not limited only to the exact center of the color separation lens array 130 and may be defined as a position where the CRA is within a predetermined range. For example, the range of the center portion may be determined, for example, to within 5%, within 10%, or within 20% of the maximum CRA, according to the convenience of design.

The arrangement of the nanoposts of the color separation lens array 130 may be different in the center portion and the peripheral portion and, for example, if the nanoposts NP of the color separation lens array 130 are arranged in two layers, the nanoposts NP arranged in the second layer may be shifted toward the center portion.

As described above, similar to the color separation lens array 130 of which the center portion and the peripheral portion are separately designed, in designing the organic photoelectric conversion layer 150 and the spectroscopic filter layer 190, the CRA may be considered.

The thickness of the organic photoelectric conversion layer 180 may also be different in the center portion and the peripheral portion. As the CRA is increased, the thickness of the organic photoelectric conversion layer 150 may become thinner from the center portion to the peripheral portion to offset the light path being lengthened as the CRA is increased.

The organic photoelectric conversion layer 150 may include a plurality of cells 180a and 180b having different CRA positions, and the pixels facing the plurality of cells 180a and 180b may have the same color. In this case, the thickness of the cell 180b in a position where the CRA is great may be less than the thickness of the cell 180a in a position where the CRA is small.

The performance of the spectroscopic filters provided in the spectroscopic filter layer 190, for example, the bandwidth of the transmission spectrum may depend on the angle of incident light. Thus, the CRA may be considered in the design of the spectroscopic filter layer 190.

The spectroscopic filter layer 190 may include two spectroscopic filters 190a and 190b with different CRA positions, and the color of the pixels facing the two spectroscopic filters 190a and 190b may be the same. In this case, the detailed structures of the two spectroscopic filters 190a and 190b may be different from each other. By making the detailed structure of the two spectroscopic filters 190a and 190b different, similar performance may be shown even in different incidence angle positions. For example, the two spectroscopic filters 190a and 190b may have different resonator thicknesses RL or may be the spectroscopic filter SF1 of FIG. 8 in which the first and second reflectors 810 and 820 have different details. As another example, the two spectroscopic filters 190a and 190b may be the spectroscopic filter SF2 of FIG. 9 in which the sizes or arrangements of the nanostructure NS are different from each other.

In some embodiments, the change in the performance of the spectroscopic filter according to the incidence angle may be used in a signal processing process. In the signal processing process of increasing the color accuracy, changes according to the incidence angle, for example the CRA, may be learned and applied to a correction algorithm. In some embodiments, the structure of the spectroscopic filter may be changed according to the incidence angle such that the transmission band is constantly maintained.

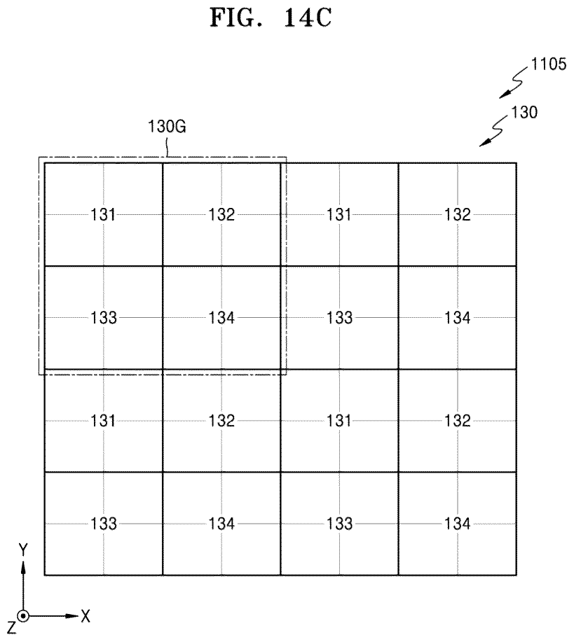

FIG. 14A is a plan view showing a color arrangement of a pixel array according to an embodiment, FIG. 14B is a plan view showing a pixel arrangement of a sensor substrate provided in the pixel array of FIG. 14A, and FIG. 14C is a plan view showing an arrangement of the pixel corresponding areas corresponding to the unit pixel group of FIG. 14B.

The color arrangement shown in FIG. 14A is similar to the Bayer pattern shown in FIG. 2A, but differs from the general Bayer pattern in that the same color is adjacent in a 2×2 arrangement. A 2×2 arrangement of a green G color, a 2×2 arrangement of a blue B color, a 2×2 arrangement of a red R color, and a 2×2 arrangement of a green G color may form a unit pattern UP, and the unit pattern UP may be two-dimensionally arranged repeatedly. Such a color arrangement may be used to improve sensitivity in an ultra-compact image sensor and may, for example, be used in a binning mode operation according to an illuminance situation. The arrangement of the same color is illustrated as a 2×2 arrangement, but embodiments are not limited thereto, and may be a N×N arrangement (where N is an integer of 2 or more).

Referring to FIG. 14B, the pixel PX arrangement of the sensor substrate 110 may be arranged correspondingly to the color arrangement. The sensor substrate 110 may include a plurality of unit pixel groups 110G. The unit pixel group 110G may correspond one-to-one to the unit pattern UP shown in FIG. 14A. The unit pixel group 110G may include the first pixel group 111G, the second pixel group 112G, the third pixel group 113G, and the fourth pixel group 114G. The first pixel group 111G may include four first pixels 11, 12, 13, and 14 having a 2×2 arrangement, the second pixel group 112G may include four second pixels 21, 22, 23, and 24 having a 2×2 arrangement, the third pixel group 113G may include four third pixels 31, 32, 33, and 34 having a 2×2 arrangement, and the fourth pixel group 114G may include four fourth pixels 41, 42, 43, and 44 having a 2×2 arrangement. In addition, these pixels PX may each include a plurality of light detection cells that independently detect incident light. For example, as shown in the drawing, one pixel PX may include four light detection cells c1, c2, c3, and c4. As described with reference to FIG. 2B, the light detection cells may each operate as an independent pixel or may be used as an autofocus pixel.

Referring to FIG. 14C, the color separation lens array 130 may include a plurality of pixel corresponding groups 130G respectively corresponding to the plurality of unit pixel groups 110G of the sensor substrate 110 illustrated in FIG. 14B. The pixel corresponding group 130G may include the first pixel corresponding area 131 facing the first pixel group 111G, the second pixel corresponding area 132 facing the second pixel group 112G, the third pixel corresponding area 133 facing the third pixel group 113G, and the fourth pixel corresponding area 134 facing the fourth pixel group 114G. The first to fourth pixel corresponding areas 131, 132, 133, and 134 may each include a plurality of nanoposts. The shape and arrangement of the plurality of nanoposts may be determined such that incident light is separated according to the wavelengths and is multiply condensed on pixels arranged in the sensor substrate 110 and arranged continuously to show the same color.

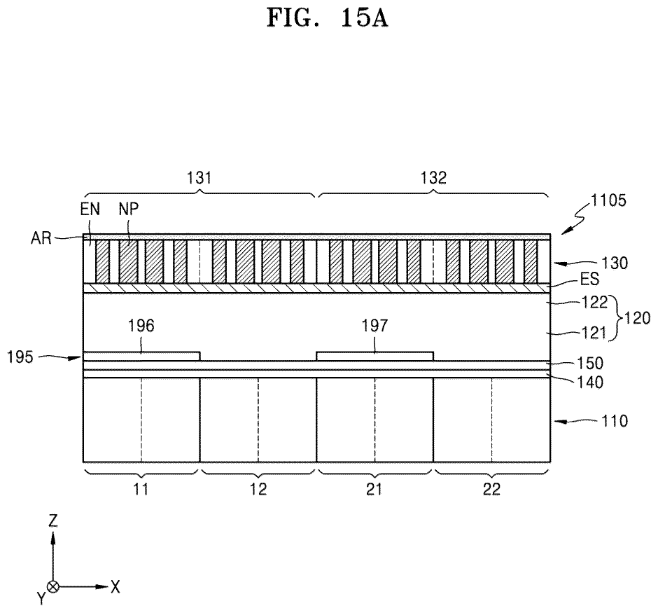

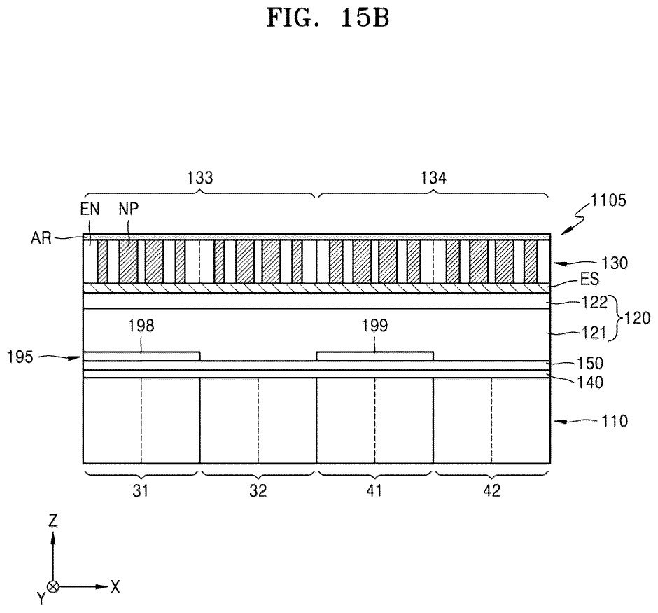

FIGS. 15A and 15B are cross-sectional views showing the pixel array of FIG. 14A in different cross-sections.

In the spectroscopic filter layer 195 including the pixel array 1105 having the above color arrangement, the first spectroscopic filter 196 may face one of the first pixels 11, 12, 13, and 14 included in the first pixel group 111G, the second spectroscopic filter 197 may face one of the second pixels 21, 22, 23, and 24 included in the second pixel group 112G, the third spectroscopic filter 198 may face one of the third pixels 31, 32, 33, and 34 included in the third pixel group 113G, and the fourth spectroscopic filter 199 may face one of the fourth pixels 41, 42, 43, and 44 included in the fourth pixel group 114G.

The first to fourth spectroscopic filters 195, 196, 197, and 198 may correspond to the spectroscopic filter SF1 of FIG. 8 or the spectroscopic filter SF2 of FIG. 9 having a configuration depending on the color of the pixel facing the spectroscopic filter, similar to the first to fourth spectroscopic filters 191, 192, 193, and 194 described above.

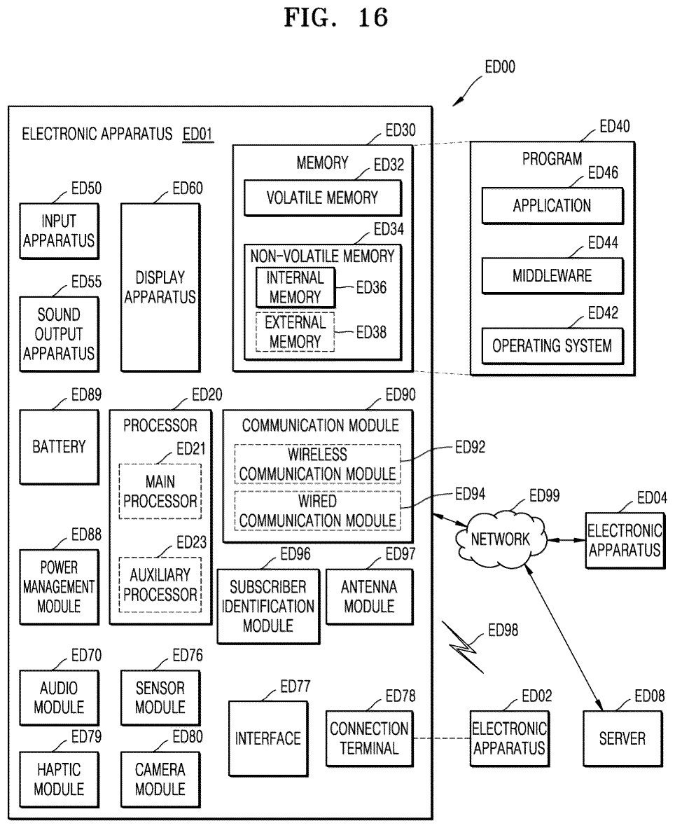

FIG. 16 is a block diagram schematically showing an electronic apparatus including an image sensor according to embodiments. Referring to FIG. 16, in a network environment ED00, the electronic apparatus ED01 may communicate with another electronic apparatus ED02 through a first network ED98 (e.g., a short-range wireless communication network, etc.) or may communicate with another electronic apparatus ED04 and/or server ED08 through a second network ED99 (e.g. a long-range wireless communication network, etc.). The electronic apparatus ED01 may communicate with the electronic apparatus ED04 through the server ED08. The electronic apparatus ED01 may include a processor ED20, a memory ED30, an input apparatus ED50, a sound output apparatus ED55, a display apparatus ED60, an audio module ED70, a sensor module ED76, an interface ED77, a haptic module ED79, a camera module ED80, a power management module ED88, a battery ED89, a communication module ED90, a subscriber identification module ED96, and/or an antenna module ED97. In the electronic apparatus ED01, some of the above elements (e.g., the display apparatus ED60, etc.) may be omitted or other elements may be added. Some of the elements may be implemented as an integrated circuit. For example, the sensor module ED76 (which may include, for example, a fingerprint sensor, an iris sensor, an illuminance sensor, etc.) may be embedded in the display apparatus ED60 (which may include, for example, a a display, etc.).

The processor ED20 may execute software (e.g., a program ED40) to control another element or a plurality of other elements (e.g., hardware, software components, etc.) of the electronic apparatus ED01 connected to the processor ED20 and may perform processing or operation of various data. As part of the data processing or operation, the processor ED20 may load commands and/or data received from other components (e.g., the sensor module ED76, the communication module ED90, etc.) onto the volatile memory ED32, process the commands and/or data stored in the volatile memory ED32, and store result data on the non-volatile memory ED34. The processor ED20 may include a main processor ED21 (e.g., a central processing apparatus, an application processor, etc.) and an auxiliary processor ED23 (e.g., a graphic processing apparatus, an image signal processor (ISP), a sensor hub processor, a communication processor, etc.) that may be operated independently from or together with the main processor ED21. The auxiliary processor ED23 may use less power than the main processor ED21 and may perform specialized functions.

When the main processor ED21 is in an inactive state (e.g., a sleep state) or in an active state (e.g., an application execution state), the auxiliary processor ED23 may, either in place of or in conjunction with the main processor ED21, control functions and/or states of some components (e.g., the display apparatus ED60, the sensor module ED76, the communication module ED90, etc.) of the components of the electronic apparatus ED01. The auxiliary processor ED23 (e.g., an ISP, a communication processor, etc.) may be implemented as a portion of other components (e.g., the camera module ED80, the communication module ED90, etc.) that are technically related to the auxiliary processor ED23.

The memory ED30 may store various data required by the components (e.g., the processor ED20, the sensor module ED76, etc.) of the electronic apparatus ED01. Data may include, for example, software (e.g., the program ED40, etc.) and input data and/or output data of commands related to the software. The memory ED30 may include the volatile memory ED32 and/or the non-volatile memory ED34.

The program ED40 may be stored as a software in the memory ED30 and may include an operating system ED42, middleware ED44, and/or an application ED46.

The input apparatus ED50 may receive, from the outside of the electronic apparatus ED01 (e.g., from a user, etc.), commands and/or data to be used in the components (e.g., the processor ED20) of the electronic apparatus ED01. The input apparatus ED50 may include a microphone, a mouse, a keyboard, and/or a digital pen (e.g., a stylus pen, etc.).

The sound output apparatus ED55 may output a sound signal to the outside of the electronic apparatus ED01. The sound output apparatus ED55 may include a speaker and/or a receiver. The speaker may be used for general purposes, such as playing multimedia or playing record, and the receiver may be used for receiving incoming calls. The receiver may be implemented as part of or separate from the speaker.

The display apparatus ED60 may visually provide information to the outside of the electronic apparatus ED01. The display apparatus ED60 may include a display, a hologram apparatus, or a projector and control circuitry to control a corresponding one of the display, the hologram apparatus, and the projector. The display apparatus ED60 may include touch circuitry adapted to detect a touch and/or sensor circuitry (e.g., a pressure sensor, etc.) adapted to measure the intensity of force incurred by the touch.

The audio module ED70 may convert sound to an electrical signal or convert the electrical signal to sound. The audio module ED70 may obtain the sound via the input apparatus ED50 or output the sound via the sound output apparatus ED55 and/or a speaker and/or headphone of another electronic apparatus (e.g., the electronic apparatus ED02) directly or wirelessly connected to the electronic apparatus ED01.

The sensor module ED76 may detect an operational state (e.g., power, temperature, etc.) of the electronic apparatus ED01 or an external environmental state (e.g., a state of a user, etc.), and then generate an electrical signal and/or data value corresponding to the detected state. The sensor module ED76 may include a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, and/or an illuminance sensor.

The interface ED77 may support one or more specified protocols to be used for the electronic apparatus ED01 to be connected with another electronic apparatus (e.g., the electronic apparatus ED02, etc.) directly or wirelessly. The interface ED77 may include a high definition multimedia interface (HDMI), a universal serial bus (USB) interface, a secure digital (SD) card interface, and/or an audio interface.

A connecting terminal ED78 may include a connector via which the electronic apparatus ED01 may be physically connected with another electronic apparatus (e.g., the electronic apparatus ED02, etc.). The connecting terminal ED78 may include an HDMI connector, a USB connector, a SD card connector, and/or an audio connector (e.g., a headphone connector, etc.).

The haptic module ED79 may convert an electrical signal into a mechanical stimulus (e.g., a vibration or a movement) or electrical stimulus which may be recognized by a user via one's tactile sensation or kinesthetic sensation. The haptic module ED79 may include a motor, a piezoelectric element, and/or an electric stimulator.

The camera module ED80 may capture a still image or moving images.

The camera module ED80 may include a lens assembly including one or more lenses, the image sensor 1000 described above, ISPs, and/or flashes. The lens assembly included in the camera module ED80 may collect light emitted from the subject, which is the target of image capturing.

The power management module ED88 may manage the power supplied to the electronic apparatus ED01. The power management module ED88 may be implemented as part of a power management integrated circuit (PMIC).

The battery ED89 may supply power to the components of the electronic apparatus ED01. The battery ED89 may include a primary cell which is not rechargeable, a secondary cell which is rechargeable, and/or a fuel cell.

The communication module ED90 may support establishing a direct (e.g., wired) communication channel and/or a wireless communication channel between the electronic apparatus ED01 and another electronic apparatus (e.g., the electronic apparatus ED02, the electronic apparatus ED04, the server ED08, etc.) and performing communication via the established communication channel. The communication module ED90 may include one or more communication processors that are operable independently from the processor ED20 (e.g., the application processor, etc.) and supports a direct communication and/or a wireless communication. The communication module ED90 may include a wireless communication module ED92 (e.g., a cellular communication module, a short-range wireless communication module, a global navigation satellite system (GNSS) communication module, etc.) and/or a wired communication module ED94 (e.g., a local area network (LAN) communication module, a power line communication module, etc.). A corresponding one of these communication modules may communicate with another electronic device via a first network ED98 (e.g., a short-range communication network, such as Bluetooth™, wireless-fidelity (Wi-Fi) direct, or infrared data association (IrDA)) or a second network ED99 (e.g., a long-range communication network, such as a cellular network, the Internet, or a computer network (e.g., local area network (LAN) or wide area network (WAN)). These various types of communication modules may be implemented as a single component (e.g., a single chip), or may be implemented as multi components (e.g., multi chips) separate from each other. The wireless communication module ED92 may identify and authenticate the electronic apparatus ED01 in a communication network, such as the first network ED98 and/or the second network ED99, using subscriber information (e.g., international mobile subscriber identity (IMSI)) stored in the subscriber identification module ED96.

The antenna module ED97 may transmit or receive a signal and/or power to or from the outside (e.g., from another electronic apparatus). The antenna may include a radiating element including a conductive pattern formed on a substrate (e.g., a printed circuit board (PCB)). The antenna module ED97 may include one or more antennas. If a plurality of antennas are included, an antenna appropriate for a communication scheme used in a communication network, such as the first network ED98 and/or the second network ED99, may be selected by the communication module ED90, from the plurality of antennas. Signals and/or power may be transmitted or received between the communication module ED90 and another electronic apparatus via the selected antenna. Another component (e.g., a radio frequency integrated circuit (RFIC), etc.) other than the antenna may be included as part of the antenna module ED97.

Some of the components are connected to each other through communication methods between peripheral devices (e.g., buses, general purpose input and output (GPIO), serial peripheral interface (SPI), and mobile industry processor interface (MIPI)) and may interchange signals (e.g., command and data) with each other.

The command or data may be transmitted or received between the electronic apparatus ED01 and the external electronic apparatus ED04 through the server ED08 connected to the second network ED99. The other electronic apparatuses ED02 and ED04 may be the same as or different from the electronic apparatus ED01. All or some of operations executed in the electronic apparatus ED01 may be executed in one or a plurality of the other electronic apparatuses ED02, ED04, and ED08. For example, when the electronic apparatus ED01 needs to perform a function or service, instead of executing a function or service itself, the electronic apparatus ED01 may request one or a plurality of other electronic apparatuses to perform part of or the entire function or service. One or a plurality of other electronic apparatuses that received the request may execute an additional function or service related to the request and may transmit a result of the execution to the electronic apparatus ED01. To this end, cloud computing, distributed computing, and/or client-server computing technology may be used.

FIG. 15 is a block diagram showing an example of a camera module E80 provided in the electronic apparatus ED01. Referring to FIG. 15, the camera module ED80 may include a lens assembly 1170, a flash 1120, an image sensor 1000, an image stabilizer 1140, an AF controller 1130, a memory 1150 (e.g., a buffer memory, etc.), an actuator 2280, and/or an ISP 1160.

The lens assembly 1170 may collect light emitted from a subject, that is, an object for image capturing. The lens assembly 1170 may include one or more optical lenses. The lens assembly 1170 may include a path conversion member that turns the light path to the image sensor 1000. Depending on whether the path conversion member is included and the arrangement form of the path conversion member with respect to the optical lens, the camera module ED80 may have a vertical form or a folded form. The camera module ED80 may include a plurality of lens assemblies 1170, and in this case, the camera module ED80 may be a dual camera, a 360-degree camera, or a spherical camera. Some of the plurality of lens assemblies 1170 may have the same lens properties (e.g., an angle of view, a focal length, an autofocus, an F number, an optical zoom, etc.), or different lens properties. The lens assembly 1170 may include a wide-angle lens or a telephoto lens.

The actuator 1180 may drive the lens assembly 1170. Through the actuator 1180, at least a portion of the optical lens or the path conversion member included in the lens assembly 1170 may be moved. The optical lens may move along the optical axis, and an optical zoom ratio may be adjusted by moving at least a portion of the optical lens included in the lens assembly 1170 to adjust the distance between adjacent lenses.

The actuator 1180 may adjust the position of any one optical lens included in the lens assembly 1170 such that the image sensor 1000 is arranged at a focal length of the lens assembly 1170. The actuator 1180 may drive the lens assembly 1170 according to an AF driving signal transferred from the AF controller 1130.

The flash 1120 may emit light used to strengthen light emitted or reflected from the subject. The flash 1120 may release visible light or infrared light. The flash 1120 may include one or a plurality of light-emitting diodes (LED) (e.g., a red-green-blue (RGB) LED, a white LED, an IR LED, an ultraviolet (UV) LED, etc.) and/or a xenon lamp.

The image sensor 1000 may be the image sensor 1000 described with reference to FIG. 1, and may include any one of the pixel arrays 1100, 1101, 1102, 1103, 1104, and 1105 including the variety of color separation lens arrays, a combination thereof, or a modified structure. By changing light, which is emitted or reflected from the image sensor 1000 subject and transmitted through the lens assembly 1170, to an electric signal, an image corresponding to the subject may be obtained.

As described above, the image sensor 1000 may include the organic photoelectric conversion layer and the spectroscopic filter layer together with the color separation lens array, in order to improve the color separation performance and the sensing sensitivity, thereby improving the obtained image quality.

The image stabilizer ED40 may, in response to a movement of the camera module ED80 or the electronic apparatus ED01 including the camera module ED80, move one or a plurality of lenses or image sensors 1000 included in the lens assembly 1170 in a certain direction or control (e.g., a control of read-out timing, etc.) operation characteristics of the image sensor 1000, so as to compensate for negative effects of the movement. The image stabilizer 1140 may detect the movement of the camera module ED80 or the electronic apparatus ED01 by using a gyro sensor or an acceleration sensor arranged inside or outside the camera module ED80. The image stabilizer 1140 may be optically implemented.

The AF controller 1130 may generate an AF driving signal from a sensed signal value from an AF pixel of the image sensor 1000. The AF controller 1130 may control the actuator 1180 according to the AF driving signal.

The memory 1150 may store part of an image or the entire data obtained through the image sensor 1000 for a subsequent image processing operation. For example, if a plurality of images are obtained at high speed, the obtained original data (e.g., Bayer-patterned data, high resolution data, etc.) may be stored in the memory 1150, only a low resolution image may be displayed, and original data of a selected (e.g., selected by the user, etc.) image may be transmitted to the ISP 1160. The memory 1150 may be integrated into the memory ED30 of the electronic apparatus ED01 or may be a separate memory that is independently operated.

The ISP 1160 may perform image processing for an image obtained through the image sensor 1000 or image data stored in the memory 1150. Image processing may include depth map generation, three-dimensional modeling, panorama generation, feature point extraction, image synthesis, and/or image compensation (e.g., noise reduction, resolution adjustment, brightness adjustment, blurring, softening, etc.). The ISP 1160 may perform controlling (e.g., exposure time control, lead out timing control, etc.) of components (e.g., image sensors 1000, etc.) included in the camera module ED80. The image treated by the ISP 1160 may be stored again in the memory 1150 for further processing or may be provided to an external component (e.g., the memory ED30, the display apparatus ED60, the electronic apparatus ED02, the electronic apparatus ED04, the server ED08, etc.). The ISP 1160 may be integrated into the processor ED20 or may be a separate processor operating independently of the processor ED20. If the ISP 1160 is a separate processor from the processor ED20, an image processed by the ISP 1160 may be displayed through the display apparatus ED60 after going through an additional image processing by the processor ED20.

In the ISP 1160, signal processing to increase color accuracy may be performed. In the pixel arrays 1100, 1101, 1102, 1103, 1104, and 1105 described above, the spectroscopic filter layer may include spectroscopic filters arranged only in some areas of the pixels facing the spectroscopic filter layer. Thus, in processing a signal sensed in a sensor area in a position where the spectroscopic filters are not arranged, the sensed signal transmitted through the spectroscopic filter may be reflected to increase the color accuracy.

The AF controller 1130 may be integrated into the ISP 1160. The ISP 1160 may process the signals from the autofocusing pixels of the image sensor 1000 and generate an AF signal, and the AF controller 1130 may change the AF signal to an actuator 1180 driving signal and transmit the actuator 1180 driving signal to the actuator 1180.

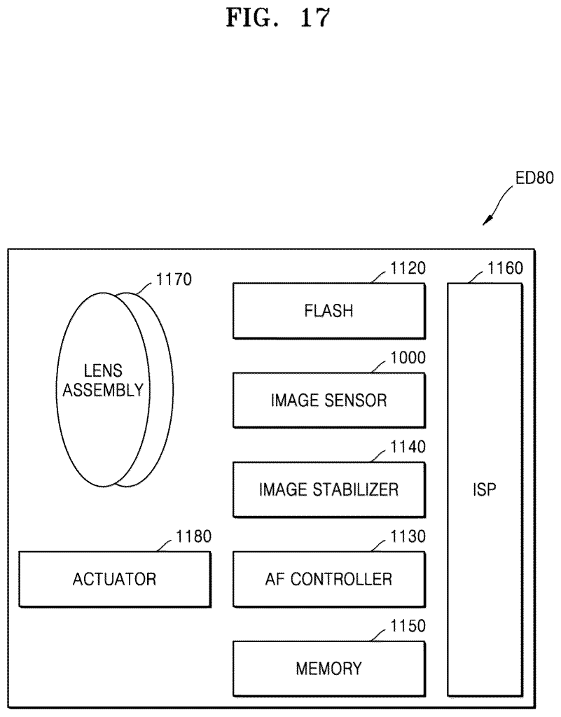

The electronic apparatus ED01 may further include one or a plurality of additional camera modules having different characteristics or functions. The camera module may include similar configurations as those of the camera module ED80 of FIG. 17 and the image sensor provided in the camera module may be implemented as a CCD sensor and/or a CMOS sensor, and may include one or a plurality of sensors selected from image sensors having different characteristics, such as an RGB sensor, a black and white (BW) sensor, an infrared (IR) sensor, and an ultraviolet (UV) sensor. In this case, one of the plurality of camera modules ED80 may be a wide-angle camera and the other may be telephoto camera. Similarly, one of the plurality of camera modules ED80 may be a front-facing camera and the other may be a rear-facing camera.

The image sensor 1000 according to embodiments may be applied to various electronic apparatuses. The image sensor according to embodiments may be applied to mobile phones or smartphones, tablets or smart tablets, digital cameras or camcorders, notebook computers, televisions, or smart televisions. For example, the smartphone or the smart tablet may include a plurality of high-resolution cameras each including a high-resolution image sensor. The high-resolution cameras may be used to extract depth information of subjects in an image, control an out focusing of the image, or automatically identify the subjects in the image.

In addition, the image sensor 1000 may be applied to smart refrigerators, security cameras, robots, medical cameras, etc. For example, the smart refrigerator may automatically recognize food in the refrigerator by using an image sensor and inform about the presence of a specific food, the types of food that are stocked or sold, etc. to the user through a smartphone. The security camera may provide an ultra-high resolution image and may allow objects or people in the moving image to be recognized even in a dark environment by using high sensitivity. The robot may be used in disasters or industrial sites that humans cannot directly access to provide high resolution images. The medical camera may provide high-resolution images for diagnosis or surgery and dynamically adjust the field of view.

In addition, the image sensor 1000 may be applied to a vehicle. The vehicle may include a plurality of vehicle cameras arranged in various positions. Each vehicle camera may include an image sensor according to an embodiment. The vehicle may provide a variety of information about the inside or surrounding of the vehicle using a plurality of vehicle cameras and may automatically recognize things or people in the image and provide information necessary for autonomous driving.

The image sensor described above and the electronic apparatus including the same have been described with reference to the embodiments shown in the drawings. However, this is an example, and it will be understood by those of ordinary skill in the art that various changes in form and details may be made.

Because the color separation lens array provided in the image sensor described above may separate incident light according to the wavelengths without absorbing or blocking the incident light, the light use efficiency of the image sensor may be improved.

The image sensor described above may be provided with an organic photoelectric conversion layer and a spectroscopic filter together with the color separation lens array, thereby improving color accuracy, sensing sensitivity, and the image quality of the image sensor.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. An image sensor comprising:
a sensor substrate comprising a plurality of pixels, wherein the plurality of pixels comprises a first pixel and a fourth pixel configured to detect green light, a second pixel configured to detect blue light, and a third pixel configured to detect red light, and wherein each pixel of the plurality of pixels comprises an inorganic photoelectric conversion material;
a color separation lens array apart from the sensor substrate in a first direction, wherein the color separation lens array is configured to separate incident light according to wavelengths, and to condense the separated incident light onto the plurality of pixels;
an organic photoelectric conversion layer between the sensor substrate and the color separation lens array; and
a spectroscopic filter layer between the organic photoelectric conversion layer and the color separation lens array.

2. The image sensor of claim 1, wherein the organic photoelectric conversion layer comprises a material configured to absorb a photon to generate an exciton.

3. The image sensor of claim 1, wherein the organic photoelectric conversion layer comprises at least one from among polyacene, rylene, rubrene, and biradicaloid.

4. The image sensor of claim 1, wherein the organic photoelectric conversion layer has a thickness of 100 nanometers (nm) or less.

5. The image sensor of claim 1, further comprising an interlayer between the sensor substrate and the organic photoelectric conversion layer.

6. The image sensor of claim 1, wherein the plurality of pixels are included in a unit pixel group from among a plurality of unit pixel groups included in the sensor substrate, and
wherein the organic photoelectric conversion layer comprises a single layer facing the plurality of unit pixel groups.

7. The image sensor of claim 1, wherein the organic photoelectric conversion layer comprises a plurality of cells facing the plurality of pixels.

8. The image sensor of claim 7, wherein each cell of the plurality of cells comprises an organic photoelectric material having a thickness corresponding to a color of a pixel facing the each cell.

9. The image sensor of claim 7, wherein each cell of the plurality of cells comprises an organic photoelectric material having a material corresponding to a color of a pixel facing the each cell.

10. The image sensor of claim 7, wherein the plurality of cells comprises a first cell facing the first pixel, a second cell facing the second pixel, a third cell facing the third pixel, and a fourth cell facing the fourth pixel,
wherein each of the first cell, the third cell, and the fourth cell comprises an organic photoelectric material, and
wherein the second cell is a dummy cell that does not include the organic photoelectric material.

11. The image sensor of claim 7, wherein the plurality of pixels comprises a plurality of first pixels corresponding to different chief ray angles,
wherein the plurality of first pixels comprises a first first pixel corresponding to a first chief ray angle, and a second first pixel corresponding to a second chief ray angle,
wherein the first chief ray angle is greater than the second chief ray angle, and
wherein a thickness of an organic photoelectric material included in a first cell facing the first first pixel is less than a thickness of the organic photoelectric material included in a second cell facing the second first pixel.

12. The image sensor of claim 1, wherein the spectroscopic filter layer comprises a plurality of spectroscopic filters facing the plurality of pixels, and
wherein each spectroscopic filter of the plurality of spectroscopic filters has a transmission spectrum corresponding to a color of a pixel facing the each spectroscopic filter.

13. The image sensor of claim 12, wherein a first spectroscopic filter from among the plurality of spectroscopic filters comprises two first spectroscopic filters having different chief ray angle positions and different structures from each other.

14. The image sensor of claim 12, wherein each pixel of the plurality of pixels comprises a plurality of light detection cells, and
wherein a size of the each spectroscopic filter is equal to a size of a light detection cell facing the each spectroscopic filter from among the plurality of light detection cells.

15. The image sensor of claim 12, wherein the plurality of spectroscopic filters comprise a Fabry-Perot resonator.

16. The image sensor of claim 15, wherein the each spectroscopic filter comprises a resonator having a thickness corresponding to the color of the pixel facing the each spectroscopic filter.

17. The image sensor of claim 12, wherein the each spectroscopic filter comprises a plurality of nanostructures.

18. The image sensor of claim 17, wherein a size of the plurality of nanostructures included in the each spectroscopic filter corresponds to the color of the pixel facing the each spectroscopic filter.

19. The image sensor of claim 1,
wherein the sensor substrate comprises:
a first pixel group comprising a plurality of first pixels arranged adjacently and continuously;
a second pixel group comprising a plurality of second pixels arranged adjacently and continuously;
a third pixel group comprising a plurality of third pixels arranged adjacently and continuously; and
a fourth pixel group comprising a plurality of fourth pixels arranged adjacently and continuously,
wherein the spectroscopic filter layer comprises:
a first spectroscopic filter facing one of the plurality of first pixels included in the first pixel group;
a second spectroscopic filter facing one of the plurality of second pixels included in the second pixel group;
a third spectroscopic filter facing one of the plurality of third pixels included in the third pixel group; and
a fourth spectroscopic filter facing one of the plurality of fourth pixels included in the fourth pixel group.

20. An electronic apparatus comprising:
a lens assembly comprising at least one lens and configured to form an optical image of an object;
an image sensor configured to convert the optical image into an electronic signal; and
a processor configured to process the electronic signal,
wherein the image sensor comprises:
a sensor substrate comprising a plurality of pixels, wherein the plurality of pixels comprises a first pixel and a fourth pixel configured to detect green light, a second pixel configured to detect blue light, and a third pixel configured to detect red light, wherein the plurality of pixels comprises an inorganic photoelectric conversion material;
a color separation lens array apart from the sensor substrate in a first direction, wherein the color separation lens array is configured to separate incident light according to wavelengths and to condense the separated incident light onto the plurality of pixels;
an organic photoelectric conversion layer between the sensor substrate and the color separation lens array; and
a spectroscopic filter layer between the organic photoelectric conversion layer and the color separation lens array.
